(19) United States
(12) Patent Application Publication
(10) Pub. No.: US 2025/0237948 A1
(43) Pub. Date: Jul. 24, 2025

(54) RADIATION-SENSITIVE RESIN COMPOSITION AND PATTERN FORMATION METHOD

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 18/848,176

(22) PCT Filed: Jan. 31, 2023
(86) PCT No.: PCT/JP2023/002997

§ 371 Date: Sep. 18, 2024

(30) Foreign Application Priority Data
Apr. 20, 2022 (JP) 2022-069143

(51) Int. Cl. G03F 7/038; C08F 220/18; C08F 220/28; G03F 7/00; G03F 7/004

(52) U.S. Cl. CPC G03F 7/0382; C08F 220/1807; C08F 220/1811; C08F 220/283; G03F 7/0046; G03F 7/0388; G03F 7/70008

(57) ABSTRACT

A radiation-sensitive resin composition includes a solvent and a resin including a structural unit A which includes an acid-dissociable group and a structural unit D which includes an aromatic ring. The aromatic ring has a phenolic hydroxy group and an alkyl group which is adjacent to the phenolic hydroxy group. The radiation-sensitive resin composition satisfies Condition 1 and/or Condition 2. Condition 1: the resin further includes a structural unit B which includes an organic acid anion moiety and an onium cation moiety including an aromatic ring structure having a fluorine atom. Condition 2: the radiation-sensitive resin composition further includes an onium salt which includes an organic acid anion moiety and an onium cation moiety including an aromatic ring structure having a fluorine atom.

### TECHNICAL FIELD

The present invention relates to a radiation-sensitive resin composition and a pattern formation method.

### BACKGROUND ART

A photolithography technology using a resist composition has been used for the formation of a fine circuit in a semiconductor device. As a representative procedure, for example, a resist pattern is formed on a substrate by generating an acid by irradiating a resist film with radiation through a mask pattern, and then generating a difference in the solubility in a developer between an exposed area and an unexposed area by a reaction using the acid as a catalyst.

In the photolithography technology, pattern miniaturization is promoted by using short-wavelength radiation, such as ArF excimer laser or by combining such radiation with an immersion exposure method (liquid immersion lithography). As a next-generation technology, further short-wavelength radiation, such as an electron beam, an X-ray, and an extreme ultraviolet ray (EUV) is being utilized, and a resist material containing an acid generator with a benzene ring having enhanced radiation absorption efficiency is also being studied (Patent Document 1).

### PRIOR ART DOCUMENT

### Patent Document

Patent Document 1: JP-A-2014-2359

### SUMMARY OF THE INVENTION

### Problems to be Solved by the Invention

Even in the above-described next generation technology, various resist performances equivalent to or higher than conventional performances are required in sensitivity and critical dimension uniformity (CDU) performance, which is an index of uniformity of a line width and a hole diameter, a reduced amount of development residue, and the like.

An object of the present invention is to provide a radiation-sensitive resin composition capable of exhibiting sensitivity, CDU performance, and development residue performance at a sufficient level when a next-generation technology is applied, and a pattern formation method.

### Means for Solving the Problems

To achieve the above object, the present inventors have intensively studied, and as a result have found that the above object can be achieved by using the following. This finding has led to the completion of the present invention.

The present invention relates to, in one embodiment,
a radiation-sensitive resin composition including:
a resin containing a structural unit A having an acid-dissociable group and a structural unit D having a phenolic hydroxy group; and
a solvent,
wherein
the structural unit D has a phenolic hydroxy group and an alkyl group on the same aromatic ring,
in an aromatic ring of the structural unit D, an alkyl group is bonded to a carbon atom adjacent to the carbon atom to which a phenolic hydroxy group is bonded,
provided that the radiation-sensitive resin composition further satisfies at least one selected from the group consisting of the following Conditions 1 and 2,
Condition 1: the resin is a radiation-sensitive acid generating resin further containing a structural unit B containing an organic acid anion moiety and an onium cation moiety having an aromatic ring structure having a fluorine atom,
Condition 2: the radiation-sensitive resin composition further includes an onium salt containing an organic acid anion moiety and an onium cation moiety containing an aromatic ring structure having a fluorine atom, provided that the onium salt excludes the radiation-sensitive acid generating resin.

With the radiation-sensitive resin composition, a resist film satisfying sensitivity, CDU performance, and development residue performance can be constructed. The reason for this is not clear, but can be expected as follows. Absorption of radiation such as EUV having a wavelength of 13.5 nm by fluorine atoms is very large, and this makes the radiation-sensitive resin composition highly sensitive. In addition, since the acid-dissociable group of the structural unit A in the resin has high acid-dissociation efficiency by exposure, the contrast between an exposed area and an unexposed area is increased, and superior pattern-forming performance is exhibited. It is presumed that the resist performance can be exhibited by the combination of these actions.

The present invention relates, in another embodiment, to a pattern formation method including:
a step of directly or indirectly applying the radiation-sensitive resin composition to a substrate to form a resist film;
a step of exposing the resist film to light; and
a step of developing, with a developer, the exposed resist film.

The pattern formation method uses the above-described radiation-sensitive resin composition superior in sensitivity, CDU performance, and development residue performance, and therefore a high-quality resist pattern can efficiently be formed.

### MODE FOR CARRYING OUT THE INVENTION

Hereinbelow, embodiments of the present invention will specifically be described, but the present invention is not limited to these embodiments.

### <Radiation-Sensitive Resin Composition>

A radiation-sensitive resin composition according to the present embodiment (hereinafter, also simply referred to as “composition”) contains a resin and a solvent. The composition may further contain another optional component as long as the effects of the present disclosure are not impaired. When the radiation-sensitive resin composition contains the prescribed resin, the radiation-sensitive resin composition can impart high levels of sensitivity, CDU performance, and development residue performance to a resulting resist film.

### <Resin>

The resin is an aggregate (G1) of a polymer containing a structural unit A having an acid-dissociable group, a structural unit B containing an organic acid anion moiety and an onium cation moiety containing an aromatic ring structure having a fluorine atom, and a structural unit D having a phenolic hydroxy group, an aggregate (G2) of a polymer containing a structural unit A having an acid-dissociable group and a structural unit D having a phenolic hydroxy group, or an aggregate containing both the aggregate (G1) and the aggregate (G2) (hereinafter, the polymer (G1) and the polymer (G2) are each also referred to as “base resin”). In the aggregate (G1) and the aggregate (G2), the structural unit D has a phenolic hydroxy group and an alkyl group on the same aromatic ring, and in an aromatic ring of the structural unit D, an alkyl group is bonded to a carbon atom adjacent to the carbon atom to which a phenolic hydroxy group is bonded. The base resins may contain a structural unit E containing a lactone structure or other structural units in addition to the structural units A, B, and D. Hereinafter, each of the structural units will be described.

### (Structural Unit A)

The structural unit A (hereinafter, also referred to as “structural unit A”) is preferably a structural unit represented by the following formula (1),

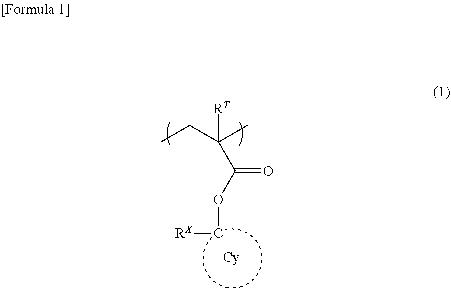

(in the formula (1),
R^{T} is a hydrogen atom, a fluorine atom, a methyl group, or a trifluoromethyl group;
R^{X} is a monovalent hydrocarbon group having 1 to 20 carbon atoms; and
Cy represents an alicyclic structure having 3 to 20 ring members and formed together with a carbon atom to which this is bonded.)

Examples of the monovalent hydrocarbon group having 1 to 20 carbon atoms represented by the R^{X} include chain hydrocarbon groups having 1 to 10 carbon atoms, monovalent alicyclic hydrocarbon groups having 3 to 20 carbon atoms, and monovalent aromatic hydrocarbon groups having 6 to 20 carbon atoms.

Examples of the chain hydrocarbon group having 1 to 10 carbon atoms include linear or branched saturated hydrocarbon groups having 1 to 10 carbon atoms and linear or branched unsaturated hydrocarbon groups having 2 to 10 carbon atoms.

Examples of the alicyclic hydrocarbon group having 3 to 20 carbon atoms include a monocyclic or polycyclic saturated hydrocarbon group and a monocyclic or polycyclic unsaturated hydrocarbon group. Preferred examples of the monocyclic saturated hydrocarbon groups include a cyclopentyl group, a cyclohexyl group, a cycloheptyl group, and a cyclooctyl group. Preferred examples of the polycyclic cycloalkyl group include bridged alicyclic hydrocarbon groups such as a norbornyl group, an adamantyl group, a tricyclodecyl group, and a tetracyclododecyl group. It is to be noted that the bridged alicyclic hydrocarbon group refers to a polycyclic alicyclic hydrocarbon group in which two carbon atoms that constitute an alicyclic ring and are not adjacent to each other are bonded by a linking group containing one or more carbon atoms.

Examples of the monovalent aromatic hydrocarbon group having 6 to 20 carbon atoms include aryl groups, such as a phenyl group, a tolyl group, a xylyl group, a naphthyl group, and an anthryl group; and aralkyl groups, such as a benzyl group, a phenethyl group, and a naphthylmethyl group.

As the R^{X}, a linear or branched saturated hydrocarbon group having 1 to 5 carbon atoms, an alicyclic hydrocarbon group having 3 to 12 carbon atoms, and an aromatic hydrocarbon group having 6 to 10 carbon atoms are preferable. In the case of the aromatic hydrocarbon group having 6 to 10 carbon atoms, an aspect in which some of the hydrogen atoms of the aromatic hydrocarbon group are substituted with halogen atoms is also preferable.

The alicyclic structure having 3 to 20 ring atoms in Cy is not particularly limited as long as it has an alicyclic structure, and may have a monocyclic, bicyclic, tricyclic, tetracyclic or more polycyclic structure, and may be any of a bridged ring structure, a spiro ring structure, a ring assembly structure in which a plurality of rings are directly bonded by a single bond or a double bond, or a combination thereof. In particular, it preferably has a bicyclic, tricyclic, or tetracyclic organic structure, and a monocyclic cycloalkyl ring structure such as cyclopentane or cyclohexane, and a polycyclic cycloalkyl ring structure such as norbornane, adamantane, tricyclo[5.2.1.0^{2,6}]decane, tetracyclo[4.4.0.1^{2,5}.1^{7,10}]dodecane, perhydronaphthalene, or perhydroanthracene are more preferable.

The structural unit represented by the formula (1) is preferably represented by the following formulas (A-1) to (A-8), for example.

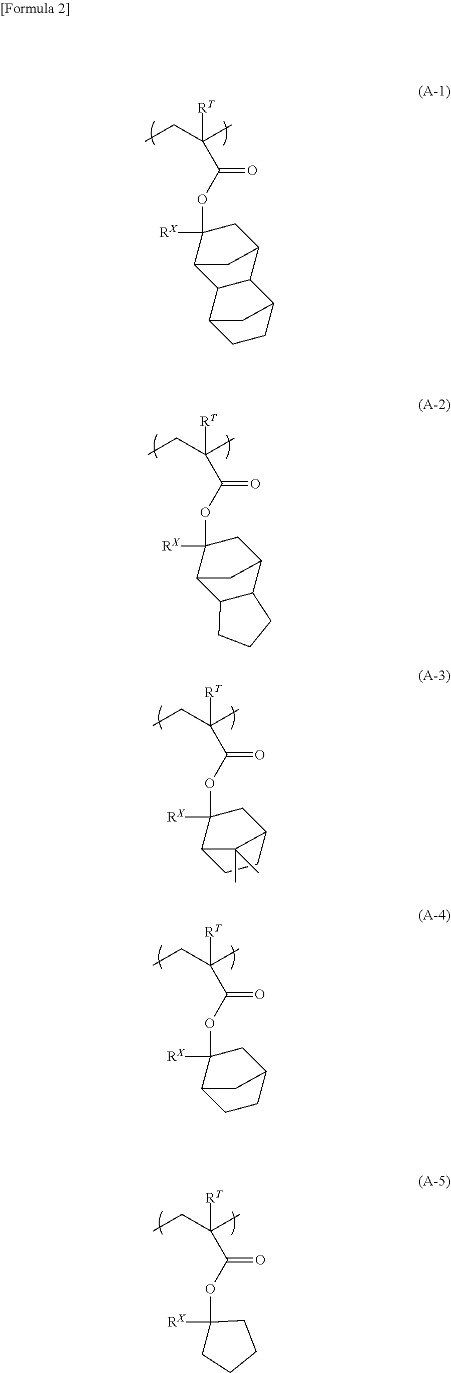

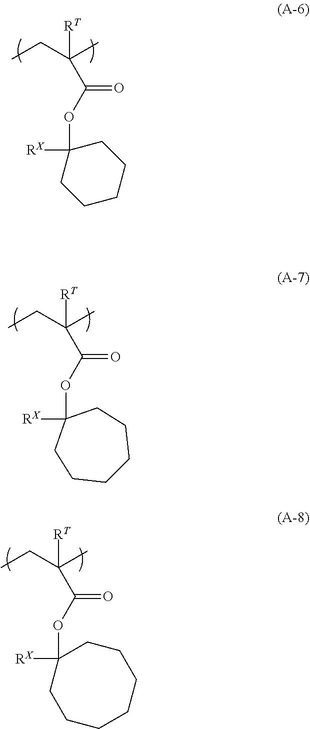

In the formulas (A-1) to (A-8), R^{T} and R^{X} have the same meanings as in the above formula (1). In particular, the structural unit A is preferably represented by, for example, the formula (A-1), (A-4), (A-5), (A-6), or (A-8).

The structural unit A is also preferably a structural unit represented by the following formula (4):

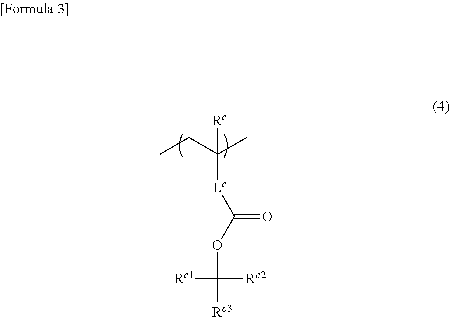

(in the formula (4),
R^{c} is a hydrogen atom, a fluorine atom, a methyl group, or a trifluoromethyl group; L^{c} is a single bond or a divalent linking group; and R^{c1}, R^{c2} and R^{c3} are each independently a monovalent hydrocarbon group having 1 to 20 carbon atoms.)

As R^{c}, a hydrogen atom or a methyl group is preferable from the viewpoint of the copolymerizability of a monomer that affords the structural unit represented by the formula (4).

Examples of the divalent linking group represented by L^{c} include an alkanediyl group, a cycloalkanediyl group, an alkenediyl group, and arylene group, —OR^{LA}—*, and —COOR^{LB}—* (* represents a bond on the carbonyl group side).

The aforementioned alkanediyl group is preferably an alkanediyl group having 1 to 8 carbon atoms.

Examples of the aforementioned cycloalkanediyl group include monocyclic cycloalkanediyl groups such as a cyclopentanediyl group and a cyclohexanediyl group; and polycyclic cycloalkanediyl groups such as a norbornanediyl group and an adamantanediyl group. The aforementioned cycloalkanediyl group is preferably a cycloalkanediyl group having 5 to 12 carbon atoms.

Examples of the aforementioned alkenediyl group include an ethenediyl group, a propenediyl group, and a butenediyl group. The aforementioned alkenediyl group is preferably an alkenediyl group having 2 to 6 carbon atoms.

Examples of R^{LA} of —OR^{LA}—* include the above-described alkanediyl group, the above-described cycloalkanediyl group, and the above-described alkenediyl group. Examples of R^{LB} of —COOR^{LB}—* include the aforementioned alkanediyl group, the aforementioned cycloalkanediyl group, the aforementioned alkenediyl group, and an arenediyl group. Examples of the arenediyl group include a benzenediyl group, a tolylene group, and a naphthalenediyl group. The aforementioned arenediyl group is preferably an arenediyl group having 6 to 15 carbon atoms.

Among them, L^{c} is preferably a single bond or —COOR^{LB}—R^{B} is preferably an alkanediyl group.

A part or all of the hydrogen atoms on a carbon atom in L^{c} may be substituted with a halogen atom such as a fluorine atom or a chlorine atom, a halogenated alkyl group such as a trifluoromethyl group, an alkoxy group such as a methoxy group, or a cyano group.

As the monovalent hydrocarbon groups having 1 to 20 carbon atoms represented by R^{c1}, R^{c2}, and R^{c3}, the groups disclosed as the monovalent hydrocarbon group having 1 to 20 carbon atoms represented by R^{X} in the above formula (1) and the like can be employed.

Among them, it is preferable that R^{c1} and R^{c2} are each independently a monovalent chain hydrocarbon group having 1 to 10 carbon atoms, and R^{c3} is a monovalent alicyclic or aromatic hydrocarbon group having 6 to 12 carbon atoms. In addition, it is also preferable that R^{c1}, R^{c2} and R^{c3} are each independently a monovalent chain hydrocarbon group having 1 to 12 carbon atoms.

The structural unit represented by the formula (4) is preferably represented by the following formulas (4-1) to (4-18).

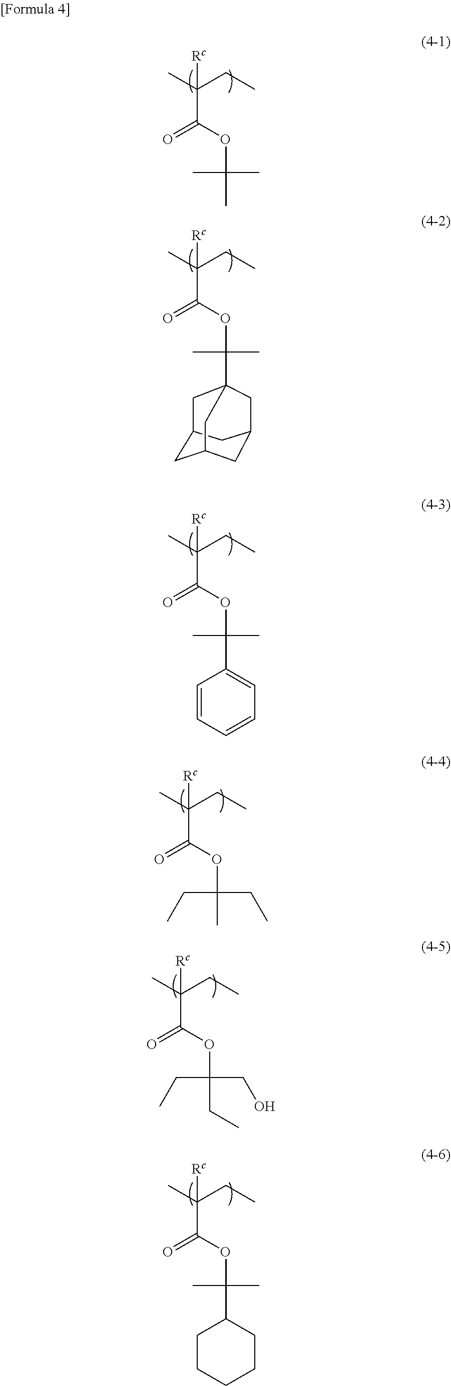

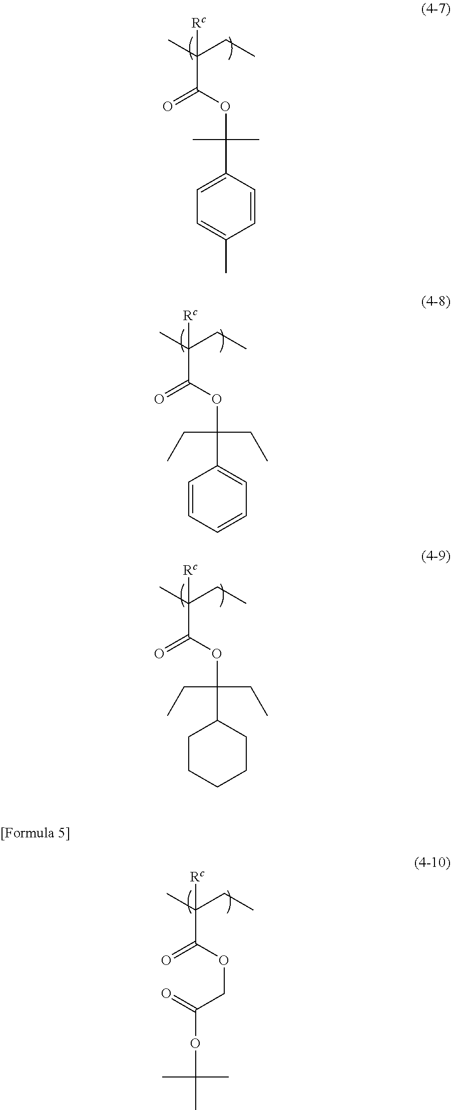

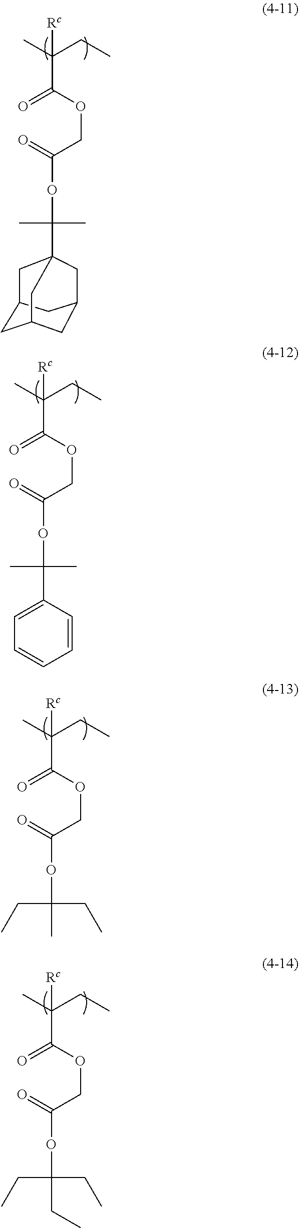

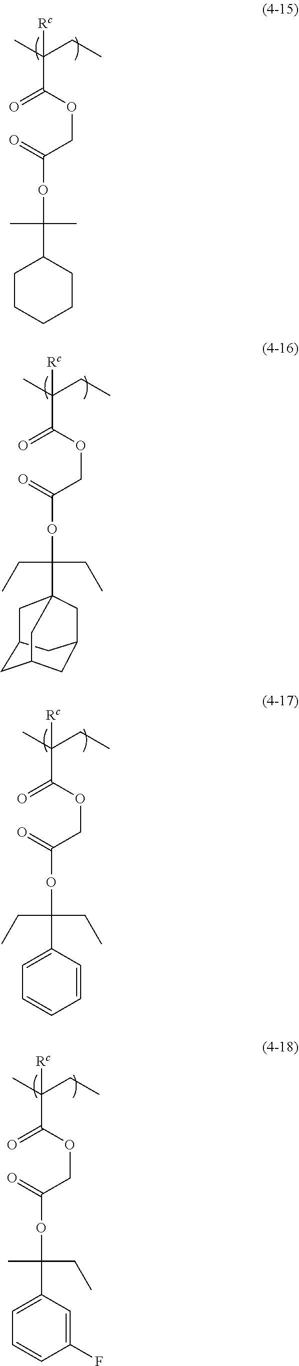

In the above formulas (4-1) to (4-18), R^{c} has the same meaning as in the above formula (4). Among them, the structural unit (II) is preferably represented by the formulas (4) to (4 to 3) and (4-10) to (4-12).

The content of the structural unit A in the resin (when there is a plurality of types of structural unit A, the total content thereof is taken) is preferably 10 mol % or more, more preferably 20 mol % or more, and still more preferably 30 mol % or more based on all structural units constituting the resin. The content is preferably 80 mol % or less, more preferably 70 mol % or less, and still more preferably 60 mol % or less. When the content of the structural unit A is adjusted to within the above range, the sensitivity and CDU performance of the radiation-sensitive resin composition can be further improved.

### (Structural Unit B)

The structural unit B (hereinafter also referred to as “structural unit B”) is a structural unit containing an organic acid anion moiety and an onium cation moiety containing an aromatic ring structure having a fluorine atom. In other words, the structural unit B contains an organic acid anion moiety and an onium cation moiety, and the onium cation moiety contains an aromatic ring structure having a fluorine atom.

The structural unit B is a structural unit derived from a monomer having a structure that is decomposed through exposure to light to generate an acid. Therefore, the resin containing the structural unit B functions as a radiation-sensitive acid generating resin. Examples of the onium cation in the structural unit B include a sulfonium cation and an iodonium cation.

The onium cation in the structural unit B is preferably a sulfonium cation, and the monomer to afford such a structural unit B is preferably, for example, a structural unit derived from a monomer represented by the following formula (2) or a monomer represented by the following formula (3),

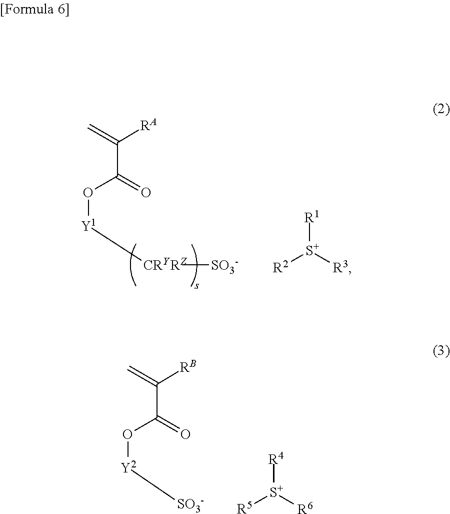

(in the formulas (2) and (3),
R^{A} and R^{B} are each a hydrogen atom, a fluorine atom, a methyl group, or a trifluoromethyl group;
R^{Y} and R^{Z} are independently a hydrogen atom, a fluorine atom, or a fluorinated hydrocarbon group, and at least one of R^{Y} and R^{Z} is a fluorine atom or a fluorinated hydrocarbon group; when there are a plurality of R^{Y}s and a plurality of R^{Z}s, they each may be the same or different;
s is an integer of 1 to 20;
R¹ to R³ are independently a monovalent hydrocarbon group, and at least one of R¹ to R³ is an aromatic ring having a fluorine atom;
R⁴ to R⁶ are independently a monovalent hydrocarbon group, and at least one of R⁴ to R⁶ is an aromatic ring having a fluorine atom;
Y¹ is a single bond or —Y¹¹—C(═O)—C—; Y¹¹ is a divalent hydrocarbon group having 1 to 20 carbon atoms or a divalent hydrocarbon group having 1 to 20 carbon atoms and containing a hetero atom;
Y² is a single bond, a methylene group, an ethylene group, a phenylene group, a fluorinated phenylene group, —O—Y²¹—, —C(═O)—O—Y²¹—, or —C(═O)—NH—Y²¹—; Y²¹ is an alkanediyl group having 1 to 6 carbon atoms, an alkenediyl group having 2 to 6 carbon atoms, or a phenylene group, and may contain a carbonyl group, an ester linkage, an ether linkage, or a hydroxy group; and the alkanediyl group having 1 to 6 carbon atoms, the alkenediyl group having 2 to 6 carbon atoms, and the phenylene group each may be substituted with a fluorine atom.)

In the formulas (2) and (3), R^{Y} and R^{Z} are independently a hydrogen atom, a fluorine atom, or a monovalent fluorinated hydrocarbon group having 1 to 20 carbon atoms, and at least one of RY and R^{Z} is a fluorine atom or a fluorinated hydrocarbon group. The hydrocarbon group constituting the monovalent fluorinated hydrocarbon group may be linear, branched, or cyclic, and examples thereof include alkyl groups such as a methyl group, an ethyl group, a n-propyl group, an isopropyl group, a n-butyl group, and a tert-butyl group; cycloalkyl groups such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups such as a vinyl group, an allyl group, a propenyl group, a butenyl group, a hexenyl group, and a cyclohexenyl group; aryl groups such as a phenyl group, a naphthyl group, and a thienyl group; and aralkyl groups such as a benzyl group, a 1-phenylethyl group, and a 2-phenylethyl group. Examples of the monovalent fluorinated hydrocarbon group include those in which some or all of hydrogen atoms of these hydrocarbon groups are replaced by a fluorine atom-containing group. when there are a plurality of R^{Y}s and a plurality of R^{Z}s, they each may be the same or different.

In the formula (2), when Y¹ is —Y¹¹—C(═O)—O—, examples of the divalent hydrocarbon group having 1 to 20 carbon atoms and optionally containing a heteroatom represented by Y¹¹ include, but are not limited to, those shown below. Incidentally, any hydrogen atom contained in the structures shown below may be substituted with a substituent containing a hetero atom, and examples of such a substituent include a halogen atom (fluorine atom, chlorine atom, bromine atom, and iodine atom), a carboxy group, a hydroxy group, a thiol group, and an amino group. Among them, Y¹¹ is preferably a divalent aromatic hydrocarbon group containing iodine.

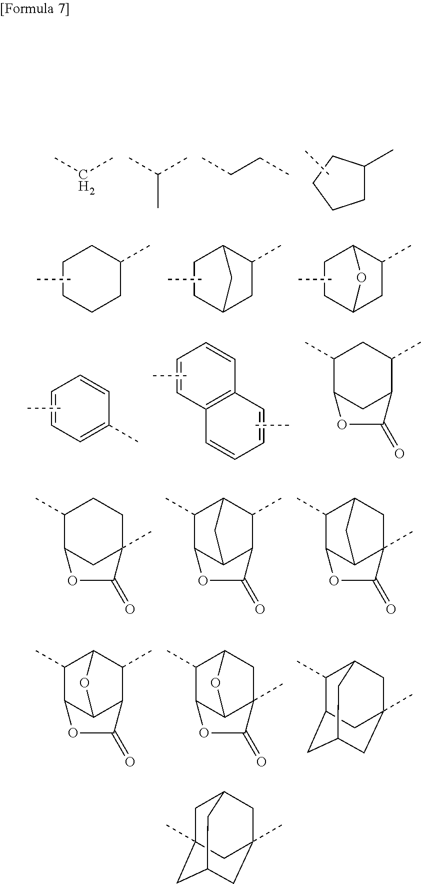

(In the formulas, the broken lines are bonds with an oxygen atom and a carbon atom in the formula (2).)

Examples of the organic acid anion moiety of the monomer that affords the structural unit B include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are replaced by an atom or group other than an iodine atom such as a hydrogen atom or other substituent.

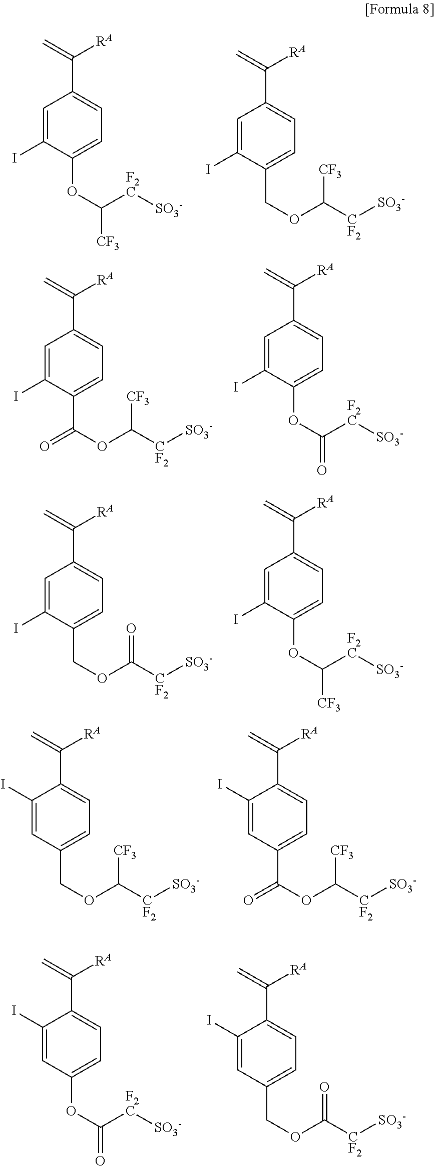

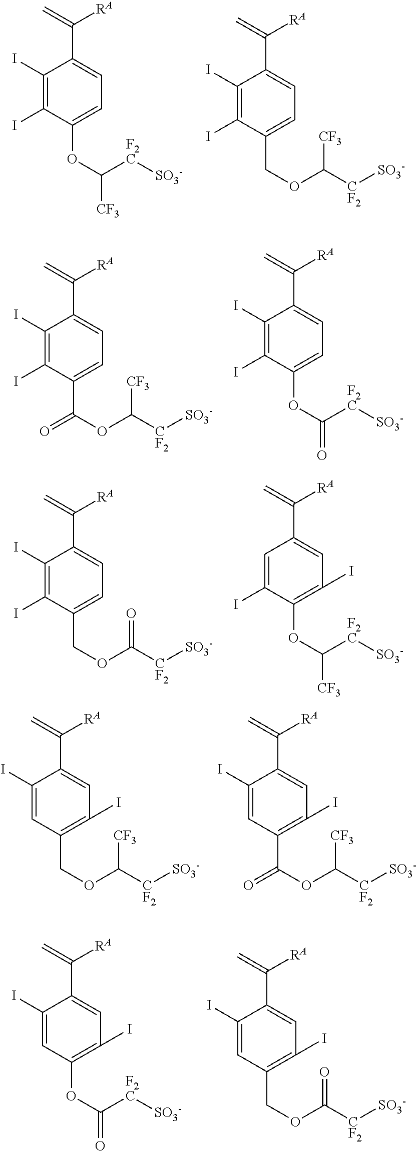

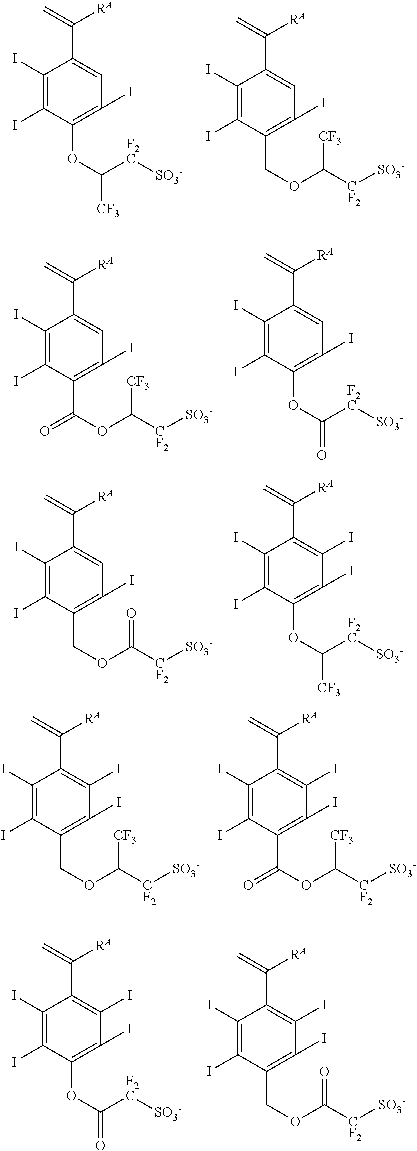

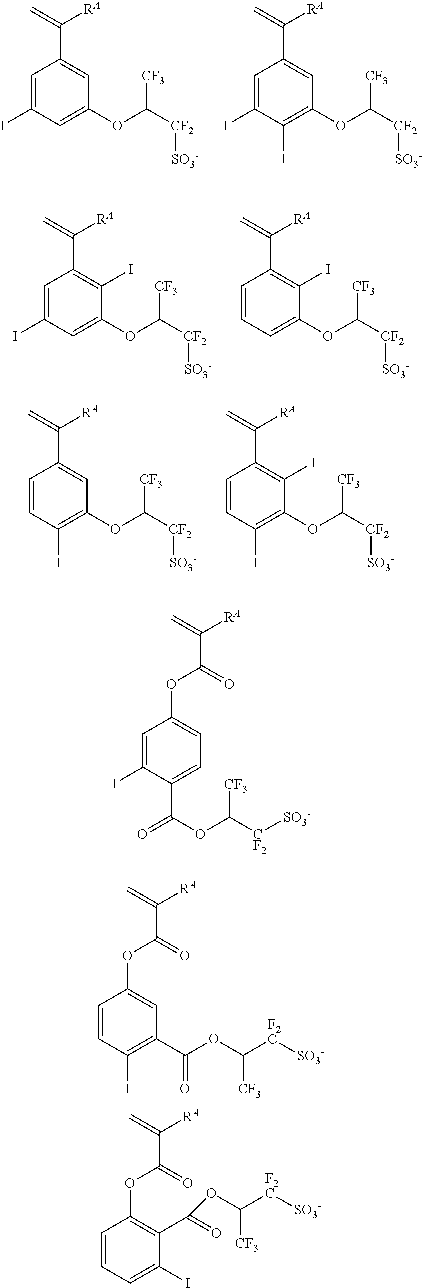

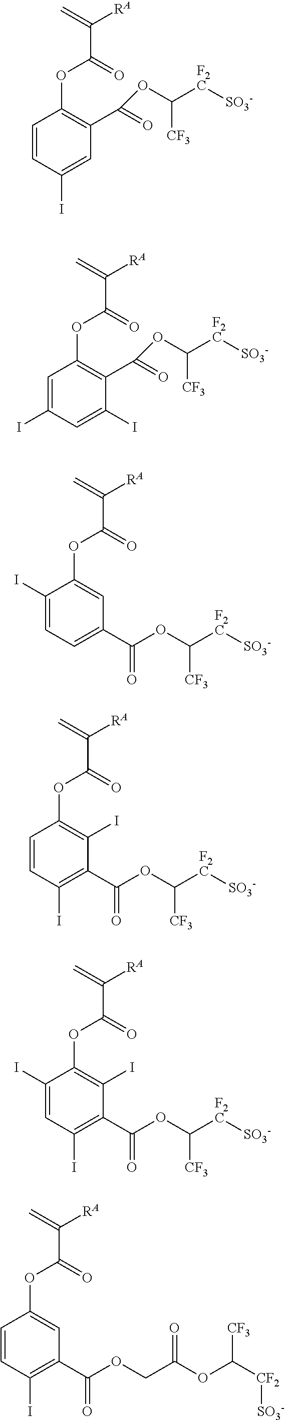

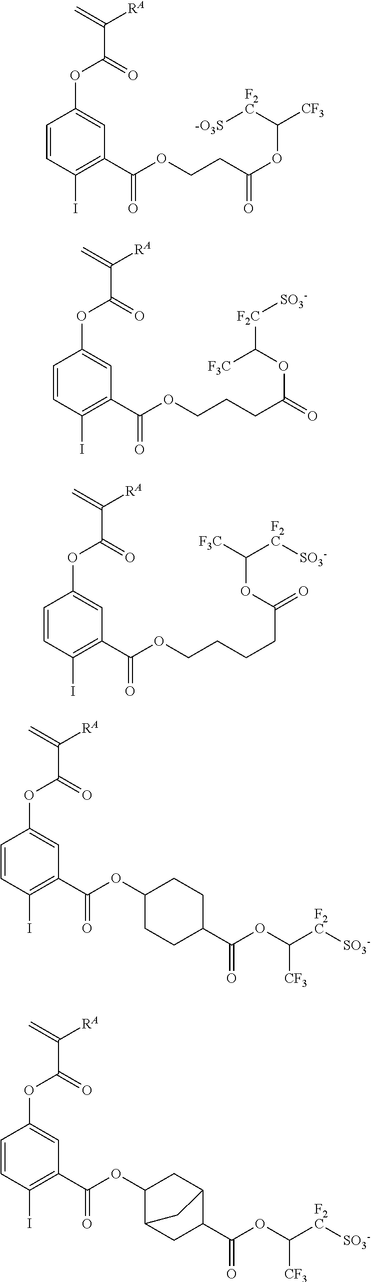

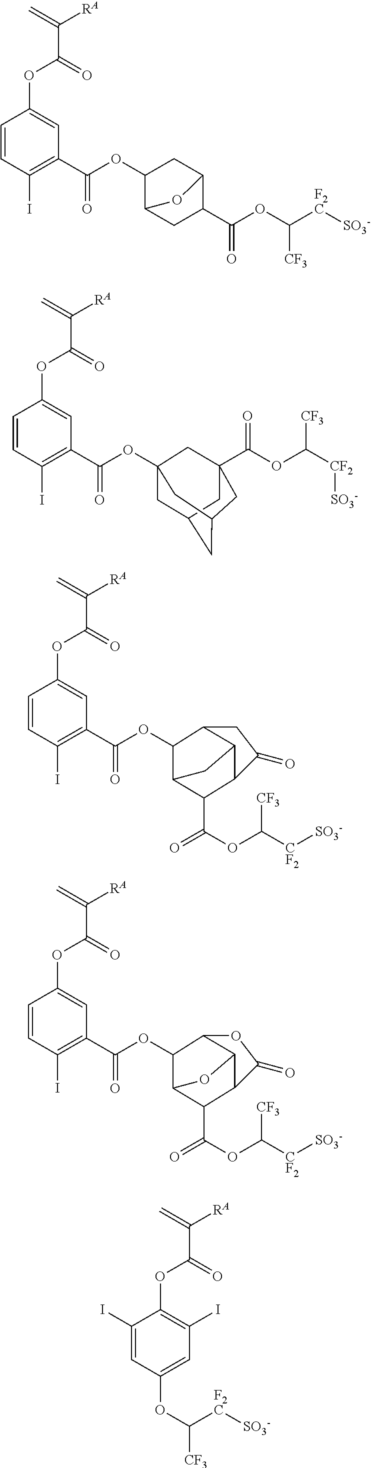

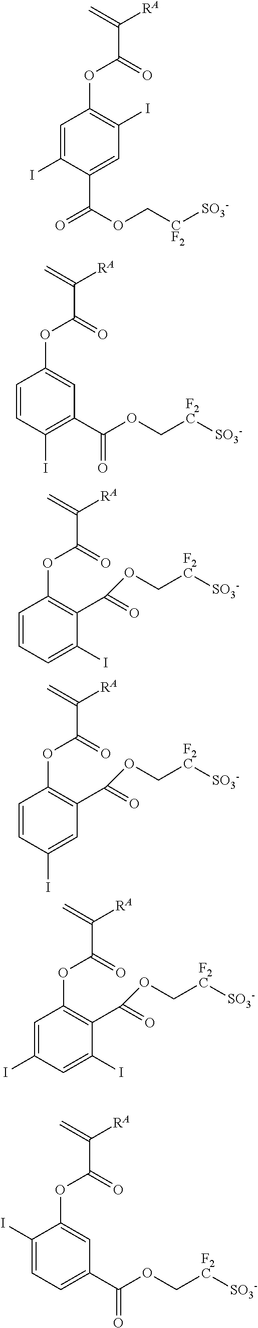

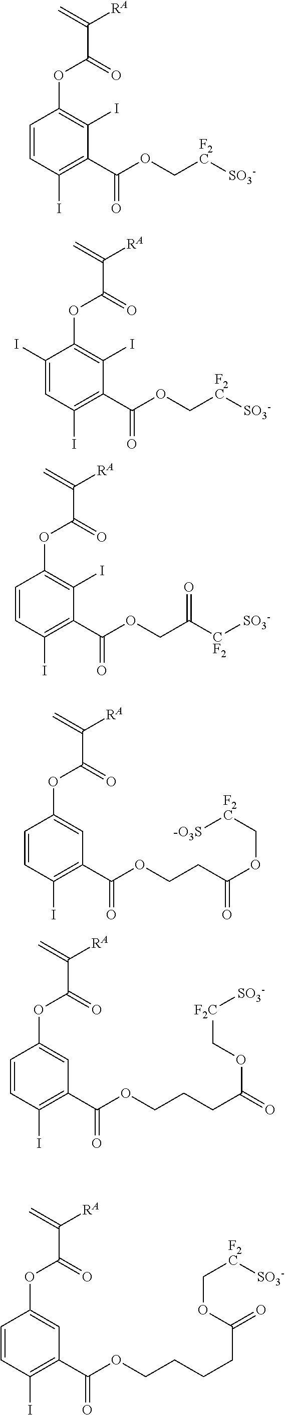

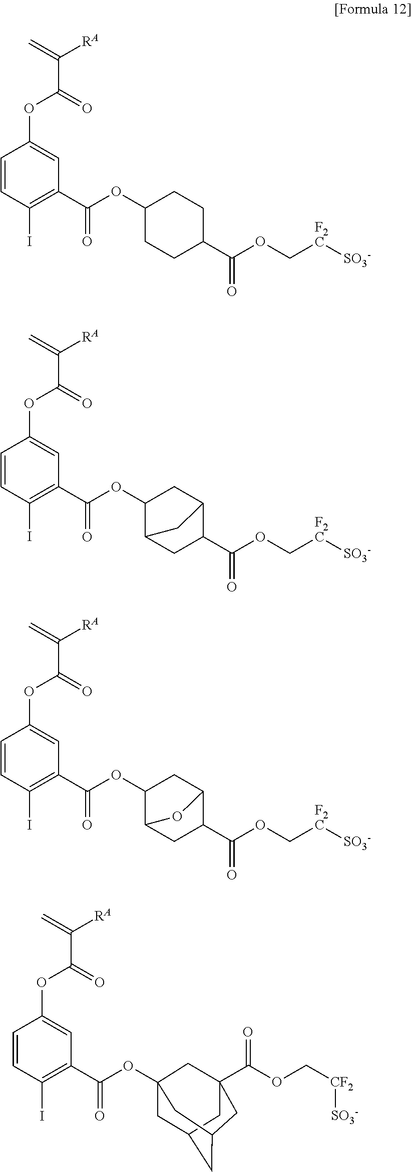

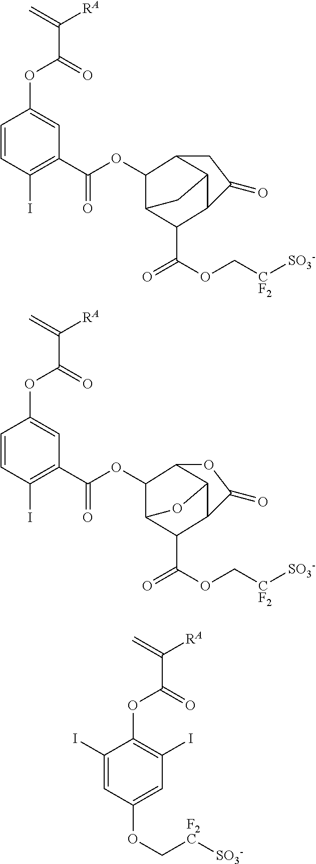

In the formulas (2) and (3), R¹ to R³ are independently a monovalent hydrocarbon group, provided that at least one of R¹ to R³ is an aromatic ring having a fluorine atom, and R⁴ to R⁶ are independently a monovalent hydrocarbon group, provided that at least one of R⁴ to R⁶ is an aromatic ring having a fluorine atom. In the present description, the “aromatic ring having a fluorine atom” refers to a structure in which some or all of hydrogen atoms contained in the aromatic ring are replaced by a fluorine atom or a fluorinated hydrocarbon group (preferably a perfluorohydrocarbon group). The monovalent hydrocarbon group may be linear, branched, or cyclic, and examples thereof include those the same as those disclosed as examples of the hydrocarbon group constituting the fluorinated hydrocarbon group in RY and R^{Z}, and an aryl group is preferable. Some of the hydrogen atoms of these groups may be replaced by a group containing a heteroatom such as an oxygen atom, a sulfur atom, a nitrogen atom, or a halogen atom. Any two of R¹ to R³ may be bonded to each other to form a ring together with the sulfur atom to which they are bonded, and any two of R⁴ to R⁶ may be bonded to each other to form a ring together with the sulfur atom to which they are bonded.

The onium cation moiety in the formulas (2) and (3) is preferably represented by the following formula (Q-1).

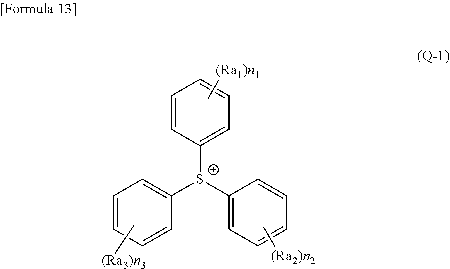

In the formula (Q-1), Ra₁ and Ra₂ each independently represent a substituent. n₁ represents an integer of 0 to 5, and when n₁ is 2 or more, the plurality of Ra₁'s may be the same or different. n₂ represents an integer of 0 to 5, and when n₂ is 2 or more, the plurality of Ra₂'s may be the same or different. n₃ represents an integer of 1 to 5, and when n₃ is 2 or more, the plurality of Ra₃'s may be the same or different. Ra₃ represents a fluorine atom or a group having one or more fluorine atoms. When n₁ is 2 or more, the plurality of Ra₁'s may be linked to each other to form a ring. When n₂ is 2 or more, the plurality of Ra₂'s may be linked to each other to form a ring. When n₁ is 1 or more and n₂ is 1 or more, Ra₁ and Ra₂ may be linked to each other to form a ring (namely, a heterocyclic ring containing a sulfur atom).

The substituent represented by Ra₁ and Ra₂ is preferably an alkyl group, a cycloalkyl group, an alkoxy group, a cycloalkyloxy group, an alkoxycarbonyl group, an alkylsulfonyl group, a cycloalkylsulfonyl group, a hydroxy group, a halogen atom, or a halogenated hydrocarbon group.

The alkyl group as Ra₁ and Ra₂ may be either linear or branched. As the alkyl group, those having 1 to 10 carbon atoms are preferable, and examples thereof include those disclosed as examples of the hydrocarbon group constituting the fluorinated hydrocarbon group in R^{Y} and R^{Z}. Among them, a methyl group, an ethyl group, a n-butyl group, and a t-butyl group are particularly preferable.

Examples of the cycloalkyl group as Ra₁ and Ra₂ include monocyclic or polycyclic cycloalkyl groups (preferably cycloalkyl groups having 3 to 20 carbon atoms), and examples thereof include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, and a cyclooctadienyl group. Among these, a cyclopropyl group, a cyclopentyl group, a cyclohexyl group, a cyclohexyl group, a cycloheptyl group, and a cyclooctyl group are particularly preferable.

Examples of the alkyl group moiety of the alkoxy group as Ra₁ and Ra₂ include those listed above as the alkyl group as Ra₁ and Ra₂. As the alkoxy group, a methoxy group, an ethoxy group, a n-propoxy group, and a n-butoxy group are particularly preferable.

Examples of the cycloalkyl group moiety of the cycloalkyloxy group as Ra₁ and Ra₂ include those listed above as the cycloalkyl group as Ra₁ and Ra₂. As the cycloalkyloxy group, a cyclopentyloxy group and a cyclohexyloxy group are particularly preferable.

Examples of the alkoxy group moiety of the alkoxycarbonyl group as Ra₁ and Ra₂ include those listed above as the alkoxy group as Ra₁ and Ra₂. As the alkoxycarbonyl group, a methoxycarbonyl group, an ethoxycarbonyl group, and a n-butoxycarbonyl group are particularly preferable.

Examples of the alkyl group moiety of the alkylsulfonyl group as Ra₁ and Ra₂ include those listed above as the alkyl group as Ra₁ and Ra₂. Examples of the cycloalkyl group moiety of the cycloalkylsulfonyl group as Ra₁ and Ra₂ include those listed above as the cycloalkyl group as Ra₁ and Ra₂. As the alkylsulfonyl group or the cycloalkylsulfonyl group, a methanesulfonyl group, an ethanesulfonyl group, a n-propanesulfonyl group, a n-butanesulfonyl group, a cyclopentanesulfonyl group, and a cyclohexanesulfonyl group are particularly preferable.

Each of the groups Ra₁ and Ra₂ may further have a substituent. Examples of the substituent include a halogen atom such as a fluorine atom (preferably a fluorine atom), a hydroxy group, a carboxy group, a cyano group, a nitro group, an alkoxy group, a cycloalkyloxy group, an alkoxyalkyl group, a cycloalkyloxyalkyl group, an alkoxycarbonyl group, a cycloalkyloxycarbonyl group, an alkoxycarbonyloxy group, and a cycloalkyloxycarbonyloxy group.

Examples of the halogen atom as Ra₁ and Ra₂ include a fluorine atom, a chlorine atom, a bromine atom, and an iodine atom, a fluorine atom, and an iodine atom is preferable.

As the halogenated hydrocarbon group as Ra₁ and Ra₂, a halogenated alkyl group is preferable. Examples of the alkyl group and the halogen atom constituting the halogenated alkyl group include those described above. Among them, a fluorinated alkyl group is preferable, and CF₃ is more preferable.

As described above, Ra₁ and Ra₂ may be linked to each other to form a ring (namely, a heterocyclic ring containing a sulfur atom). In this case, it is preferable that Ra₁ and Ra₂ are bonded to each other to form a single bond or a divalent linking group. Examples of the divalent linking group include —COO—, —OCO—, —CO—, —C—, —S—, —SO—, —SO₂—, an alkylene group, a cycloalkylene group, an alkenylene group, and combinations of two or more thereof, and those having of 20 or less carbon atoms in total are preferable. When Ra₁ and Ra₂ are linked to each other to form a ring, it is preferable that Ra₁ and Ra₂ are bonded to each other to form —COO—, —OCO—, —CO—, —C—, —S—, —SO—, —SO₂—, or a single bond. Among them, it is more preferable to form —C—, —S—, or a single bond, and it is particularly preferable to form a single bond. When n₁ is 2 or more, the plurality of Ra₁'s may be linked to each other to form a ring, and when n₂ is 2 or more, the plurality of Ra₂'s may be linked to each other to form a ring. Examples thereof include an aspect in which two Ra₁'s are linked to each other to form a naphthalene ring together with a benzene ring to which they are bonded.

Ra₃ is a fluorine atom or a group having one or more fluorine atoms. Examples of the group having a fluorine atom include groups in which an alkyl group, a cycloalkyl group, an alkoxy group, a cycloalkyloxy group, an alkoxycarbonyl group, and an alkylsulfonyl group as Ra₁ and Ra₂ are substituted with a fluorine atom. Among them, fluorinated alkyl groups are suitable, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₃, CH₂CH₂C₂F₅, CH₂C₃F₇, CH₂CH₂C₃F₇, CH₂C₄F₉, and CH₂CH₂C₄F₉ are more suitable, and CF₃ is particularly suitable.

Ra₃ is preferably a fluorine atom or CF₃, and more preferably a fluorine atom.

n₃ is preferably 1 to 3, and more preferably 1 or 2.

(n₁+n₂+n₃) is preferably 1 to 15, more preferably 1 to 9, still more preferably 2 or 6, and particularly preferably 3 to 6. When (n₁+n₂+n₃) is 1, it is preferable that n₃₌₁ and Ra₃ is a fluorine atom or CF₃. When (n₁+n₂+n₃) is 2, a combination in which n₁=n₃=1 and Ra₁ and Ra₃ are each independently a fluorine atom or CF₃ and a combination in which n₃=2 and Ra₃ is a fluorine atom or CF₃ are preferable. When (n₁+n₂+n₃) is 3, a combination in which n₁=n₂=n₃=1 and Ra₁ to Ra₃ are each independently a fluorine atom or CF₃ is preferable. When (n₁+n₂+n₃) is 4, a combination in which n₁=n₃=2 and Ra₁ and Ra₃ are each independently a fluorine atom or CF₃ is preferable. When (n₁+n₂+n₃) is 5, a combination in which n₁=n₂=1 and n₃=3 and Ra₁ to Ra₃ are each independently a fluorine atom or CF₃, a combination in which n₁=n₂=2 and n₃=1 and Ra₁ to Ra₃ are each independently a fluorine atom or CF₃, and a combination in which n₃=5 and Ra₃ are each independently a fluorine atom or CF₃ are preferable. When (n₁+n₂+n₃) is 6, a combination in which n₁=n₂=n₃=2 and Ra₁ to Ra₃ are each independently a fluorine atom or CF₃ is preferable.

Examples of such an onium cation moiety represented by the formula (Q-1) include the onium cation in the onium salt described later.

As the onium cation in the structural unit B, a diaryliodonium cation having one or more fluorine atoms is also preferable.

Examples of such a diaryliodonium cation having one or more fluorine atoms include those shown below. While all of those shown below are iodonium cation moieties containing an aromatic ring structure having a fluorine atom, a structure in which a fluorine atom is substituted with a fluorinated hydrocarbon group such as a trifluoromethyl group can also be suitably employed.

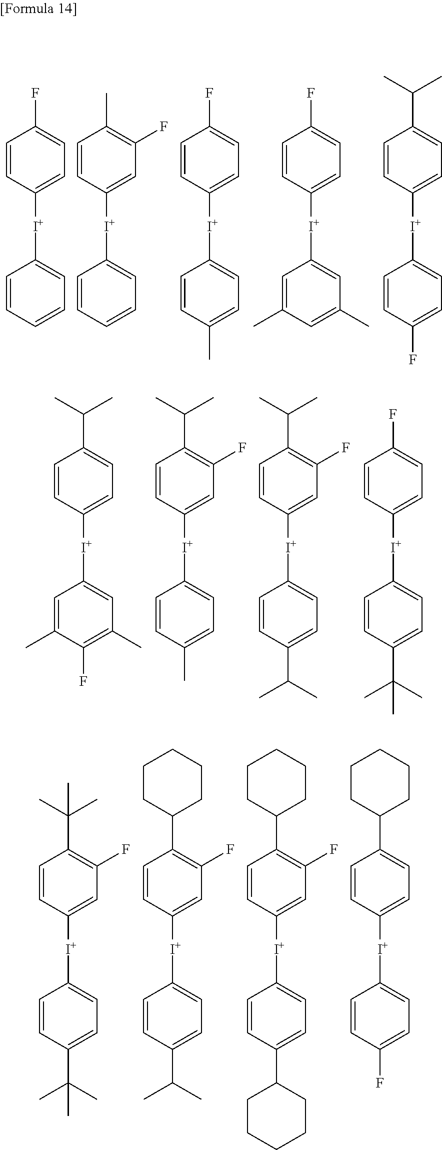

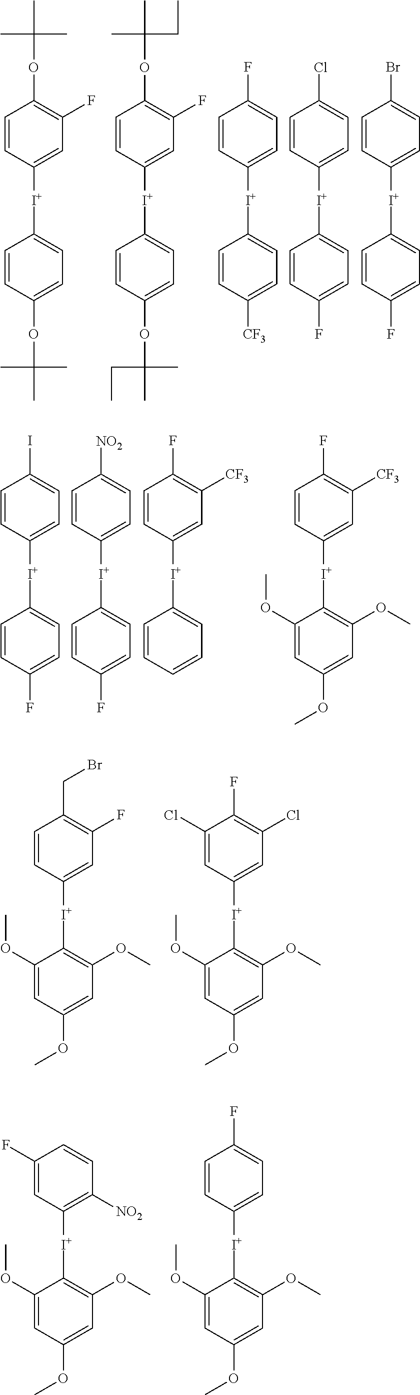

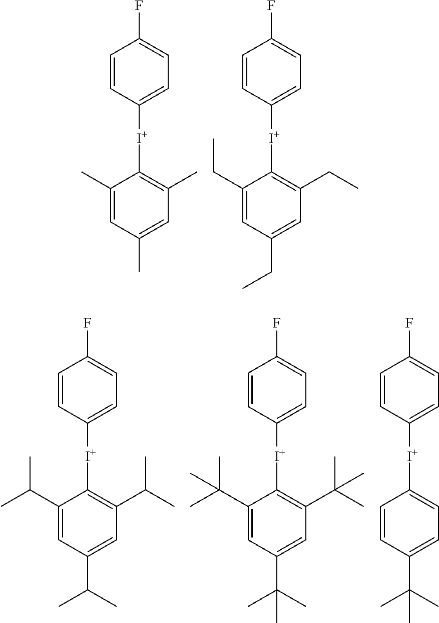

The content of the structural unit B in the resin (when there is a plurality of types of structural unit B, the total content thereof is taken) is preferably 2 mol % or more, more preferably 3 mol % or more, still more preferably 4 mol % or more, and particularly preferably 5 mol % or more based on all structural units constituting the resin. The content is preferably 30 mol % or less, more preferably 25 mol % or less, still more preferably 20 mol % or less, and particularly preferably 15 mol % or less. When the content is adjusted to within the above range, a function as a radiation-sensitive acid generating resin can be sufficiently exhibited.

### (Structural Unit D)

The structural unit D is a structural unit having a phenolic hydroxy group, and has a phenolic hydroxy group and an alkyl group on the same aromatic ring, and in the aromatic ring, an alkyl group is bonded to a carbon atom adjacent to the carbon atom to which a phenolic hydroxy group is bonded. In other words, the structural unit D is a structural unit having a phenolic hydroxy group, an alkyl group is further bonded to the aromatic ring to which the phenolic hydroxy group is bonded, and a carbon atom to which the phenolic hydroxy group is bonded and a carbon atom to which the alkyl group is bonded are directly linked. In the present invention, a phenolic hydroxy group generated through deprotection due to the action of an acid generated by exposure to light is also included as the phenolic hydroxy group of the structural unit D. The reason the effect of the present invention is exhibited when the resin contains the structural unit D is not clear, but the following is considered as one possibility. It is considered that the phenolic hydroxy group of the resin interacts with the onium cation moiety of the radiation-sensitive acid generating resin or the onium cation of the onium salt to deteriorate development defects. On the other hand, it is presumed that the presence of an alkyl group in the vicinity of the phenolic hydroxy group of the resin weakens the interaction due to steric hindrance, and as a result, development defects are improved. When KrF excimer laser light, EUV, electron beam or the like is used as radiation to be applied in an exposure step in a resist pattern formation method, the structural unit D contributes to improvement in etching resistance and improvement in the difference in solubility in a developer (namely, dissolution contrast) between an exposed area and an unexposed area. In particular, the resin can be suitably applied to pattern formation using exposure with radiation having a wavelength of 50 nm or less such as electron beam or EUV. The structural unit D is preferably represented by the following formula (D).

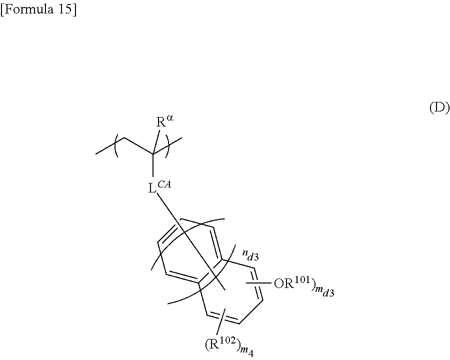

(In the formula (D),
R^{α} is a hydrogen atom, a fluorine atom, a methyl group, or a trifluoromethyl group;
L^{CA} is a single bond, —COO—*, or —O—; * is a bond on the aromatic ring side;
R¹⁰¹ is a hydrogen atom or a protective group that is deprotected by the action of an acid to form a hydrogen atom; when there is a plurality of R¹⁰¹'s, the plurality of R¹⁰¹'s is the same or different from each other, provided that at least one R¹⁰¹ is a hydrogen atom;
R¹⁰² is a cyano group, a nitro group, an alkyl group, a fluorinated alkyl group, an alkoxycarbonyloxy group, an acyl group, or an acyloxy group, provided that at least one R¹⁰² is an alkyl group,
n_{d3} is an integer of 0 to 2, m_{d3} is an integer of 1 to 8, and m₄ is an integer of 1 to 8, provided that 1≤m_{d3}+m₄≤2n_{d3}+5 is satisfied;
in the formula (D), R¹⁰² is bonded to a carbon atom adjacent to the carbon atom to which a phenolic hydroxy group is bonded, and R¹⁰² is an alkyl group.)

The R^{α} is preferably a hydrogen atom or a methyl group from the viewpoint of the copolymerizability of a monomer that affords the structural unit D.

The L^{CA} is preferably a single bond or —COO—*.

Examples of the protective group that is deprotected due to the action of the acid represented by R¹⁰¹ include groups represented by the following formulas (AL-1) to (AL-3).

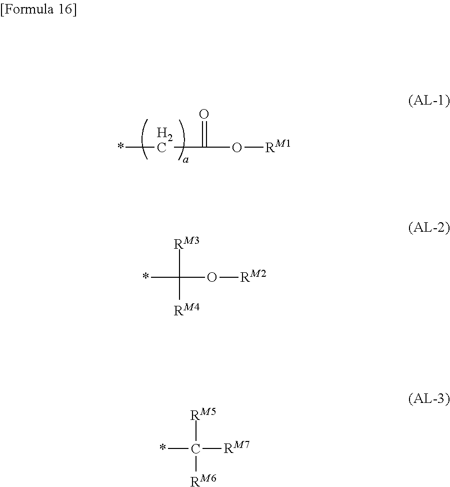

In the formulas (AL-1) and (AL-2), R^{M1} and R^{M2} are monovalent hydrocarbon groups, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 40 carbon atoms, and more preferably an alkyl group having 1 to 20 carbon atoms. In the formula (AL-1), a is an integer of 0 to 10, and preferably an integer of 1 to 5. In the formulas (AL-1) to (AL-3), * is a bond to another moiety.

In the formula (AL-2), R^{M3} and R^{M4} are each independently a hydrogen atom or a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{M2}, R^{M3}, and R^{M4} may be bonded to each other to form a ring having 3 to 20 carbon atoms together with the carbon atom or the carbon atom and the oxygen atom to which they are bonded. The ring is preferably a ring having 4 to 16 carbon atoms.

In the formula (AL-3), R^{M5}, R^{M6}, and R^{M7} are each independently a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{M5}, R^{M6}, and R^{M7} may be bonded to each other to form a ring having 3 to 20 carbon atoms together with the carbon atom to which they are bonded. The ring is preferably a ring having 5 to 16 carbon atoms, and particularly preferably an alicyclic ring.

Among them, the protective group that is deprotected due to the action of an acid is preferably a group represented by the formula (AL-3).

Examples of the alkyl group in R¹⁰² include linear or branched alkyl groups having 1 to 8 carbon atoms such as a methyl group, an ethyl group, and a propyl group. Examples of the fluorinated alkyl group include linear or branched fluorinated alkyl groups having 1 to 8 carbon atoms such as a trifluoromethyl group and a pentafluoroethyl group. Examples of the alkoxycarbonyloxy group include chain or alicyclic alkoxycarbonyloxy groups having 2 to 16 carbon atoms such as a methoxycarbonyloxy group, a butoxycarbonyloxy group, and an adamantylmethyloxycarbonyloxy group. Examples of the acyl group include aliphatic or aromatic acyl groups having 2 to 12 carbon atoms such as an acetyl group, a propionyl group, a benzoyl group, and an acryloyl group. Examples of the acyloxy group include aliphatic or aromatic acyloxy groups having 2 to 12 carbon atoms such as an acetyloxy group, a propionyloxy group, a benzoyloxy group, and an acryloyloxy group.

The n_{d3} is preferably 0 or 1, and more preferably 0.

The m_{d3} is preferably an integer of 1 to 3, and more preferably 1 or 2.

The m₄ is preferably an integer of 1 to 3, and more preferably an integer of 1 to 2.

In an aromatic ring of the structural unit D, an alkyl group may be bonded to only one carbon atom of the carbon atoms both adjacent to the carbon atom to which a phenolic hydroxy group is bonded, or alkyl groups may be bonded to both the carbon atoms. When an alkyl group is bonded to only one carbon atom of the carbon atoms both adjacent to the carbon atom to which a phenolic hydroxy group is bonded, the other carbon atom is bonded to LcA, bonded to the main chain of the resin, unsubstituted (in other words, bonded to a hydrogen atom), or bonded to another substituent other than alkyl groups.

In an aromatic ring of the structural unit D, the alkyl group bonded to the carbon atom(s) adjacent to the carbon atom to which a phenolic hydroxy group is bonded is preferably an alkyl group having 1 to 4 carbon atoms, more preferably a linear or branched alkyl group having 1 to 3 carbon atoms, still more preferably a methyl group, an ethyl group, or an isopropyl group, and particularly preferably a methyl group.

Examples of the monomer that affords such a structural unit D include 3-alkyl-4-hydroxystyrene, 3,5-dialkyl-4-hydroxystyrene, 3-alkyl-4-hydroxy-5-iodostyrene, 3,4-dihydroxy-5-alkylstyrene, 4-alkyl-3-hydroxystyrene, 2,4-dialkyl-3-hydroxystyrene, 3-alkyl-2-hydroxystyrene, 3-alkyl-4-hydroxyphenyl (meth)acrylate, 3,5-dialkyl-4-hydroxyphenyl (meth)acrylate, 3-alkyl-4-hydroxy-5-iodophenyl (meth)acrylate, 3,4-dihydroxy-5-alkylphenyl (meth)acrylate, 4-alkyl-3-hydroxyphenyl (meth)acrylate, 2,4-dialkyl-3-hydroxyphenyl (meth)acrylate, and 3-alkyl-2-hydroxyphenyl (meth)acrylate. Among them, 3-alkyl-4-hydroxystyrene, 3,5-dialkyl-4-hydroxystyrene, 3-alkyl-4-hydroxyphenyl (meth)acrylate, and 3,5-dialkyl-4-hydroxyphenyl (meth)acrylate are preferable. When these monomers have two or more alkyl groups, the plurality of alkyl groups may be the same or different.

As the structural unit D, structural units represented by the following formulas (D-1) to (D-10) (hereinafter also referred to as “structural units (D-1) to (D-10)”) and the like are preferable.

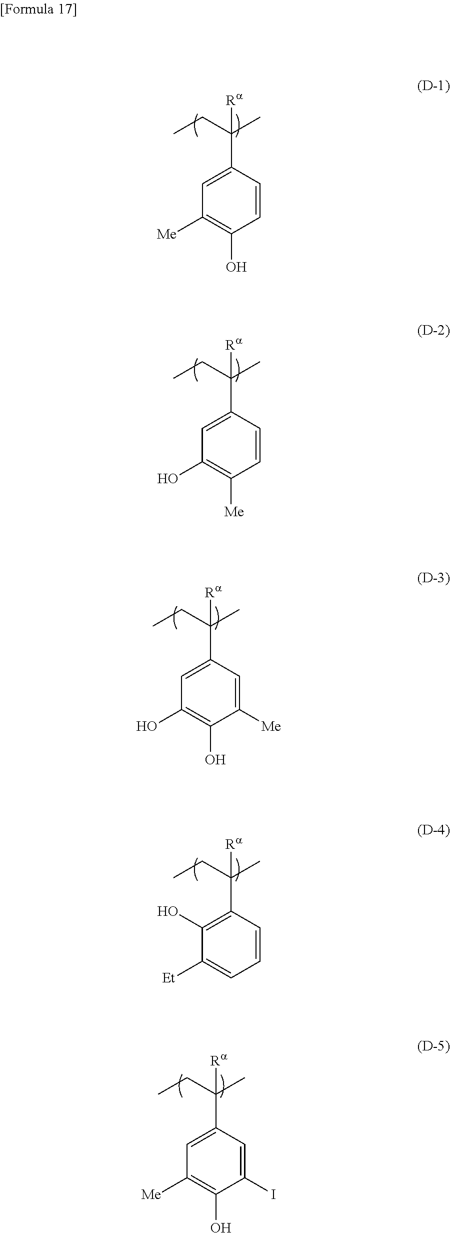

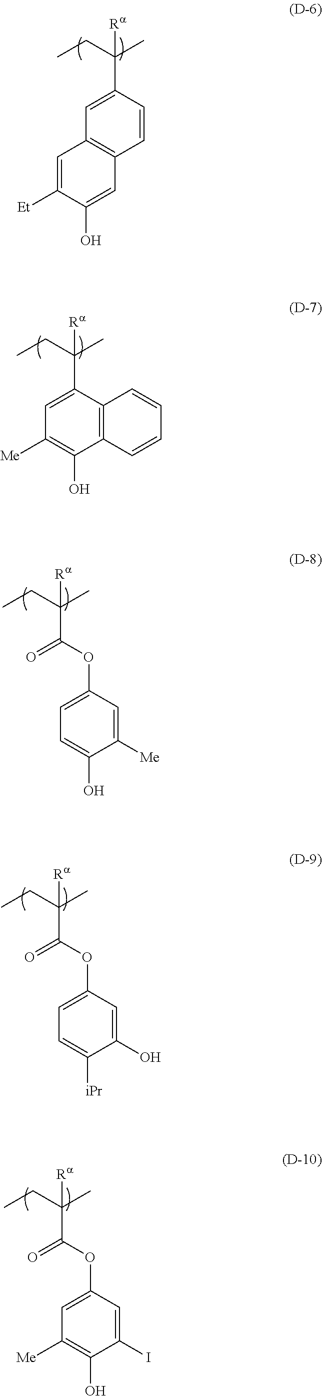

In the formulas (D-1) to (D-10), Ra is the same as in the above formula (D).

Among them, the structural units (D-1) to (D-2), (D-5), and (D-8) to (D-10) are preferable.

The content of the structural unit D (when there is a plurality of types of structural unit D, the total content thereof is taken) is preferably 5 mol % or more, more preferably 8 mol % or more, still more preferably 10 mol % or more, and particularly preferably 15 mol % or more based on all structural units constituting the resin. The content is preferably 60 mol % or less, more preferably 50 mol % or less, still more preferably 40 mol % or less, and particularly preferably 35 mol % or less. When the content of the structural unit D is adjusted to within the above range, the sensitivity, CDU performance, and resolution of the radiation-sensitive resin composition can be further improved.

The content of the structural unit D (when there is a plurality of types of structural unit D, the total content thereof is taken) is preferably 15 mol % or more, more preferably 30 mol % or more, still more preferably 50 mol % or more, and particularly preferably 65 mol % or more based on all structural units having a phenolic hydroxy group.

In the case of polymerizing a monomer having a phenolic hydroxy group such as 3-alkyl-hydroxystyrene, it is preferable to polymerize the monomer with the phenolic hydroxy group protected by a protective group such as an alkali-dissociable group and then deprotect it by hydrolysis to obtain a structural unit D.

### (Structural Unit E)

The structural unit E is a structural unit containing at least one structure selected from the group consisting of a lactone structure, a cyclic carbonate structure, and a sultone structure. When the base resin further has the structural unit E, the solubility of the base resin in a developer can be adjusted, and as a result, the lithographic performance, such as resolution, of the radiation-sensitive resin composition can be improved. In addition, the adhesion between a resist pattern formed from the base resin and a substrate can be improved.

When the structural unit E is contained, the content of the structural unit E is preferably 5 mol % or more, more preferably 10 mol % or more, and still more preferably 20 mol % or more based on all structural units constituting the base resin. The content is preferably 60 mol % or less, more preferably 50 mol % or less, and still more preferably 40 mol % or less. When the content of the structural unit E is adjusted to within the range, the lithographic performance, such as resolution, of the radiation-sensitive resin composition and the adhesion between a resist pattern to be formed and a substrate can be further improved.

A base resin of the present invention may contain a structural unit other than the structural units A, B, D, and E. Examples of such another structural unit include a structural unit having a phenolic hydroxy group (excluding the structural unit D) such as hydroxystyrene or hydroxyphenyl (meth)acrylate; a structural unit having an aliphatic hydrocarbon group (excluding the structural unit A) such as alkyl (meth)acrylate; a structural unit having an alicyclic hydrocarbon group (excluding the structural unit A) such as cycloalkyl (meth)acrylate or adamantyl (meth)acrylate; and a structural unit having an aromatic hydrocarbon group such as styrene, phenyl (meth)acrylate, or iodostyrene.

The base resin of the present invention preferably contains an iodine-substituted aromatic ring structure. The iodine-substituted aromatic ring structure of the base resin may be contained in any of the structural units A to E, or may be contained in a structural unit other than the structural units A to E. In particular, it is more preferable that the iodine-substituted aromatic ring structure is contained in any one or more of the structural units A, B, and D. Examples of the structural unit other than the structural units A to E containing an iodine-substituted aromatic ring structure include a structural unit derived from iodostyrene. The content of the iodine-substituted aromatic ring structure is preferably 1 mol % or more, more preferably 2 mol % or more, and still more preferably 3 mol % or more based on all structural units constituting the base resin. The content is preferably 30 mol % or less, more preferably 25 mol % or less, and still more preferably 20 mol % or less. By setting the content of the iodine-substituted aromatic ring structure to the above range, the radiation-sensitive resin composition can further improve the lithographic performance such as CDU performance.

### (Method for Synthesizing Resin)

The resin as a base resin can be synthesized by, for example, subjecting monomers that will afford structural units to a polymerization reaction in an appropriate solvent using a publicly known radical polymerization initiator or the like.

The molecular weight of the resin as a base resin is not particularly limited, and the weight average molecular weight (Mw) as determined by Gel Permeation Chromatography (GPC) relative to standard polystyrene is preferably 1,000 or more, more preferably 2,000 or more, still more preferably 3,000 or more, and particularly preferably 4,000 or more. The Mw of the high fluorine-containing resin is preferably 50,000 or less, more preferably 30,000 or less, still more preferably 15,000 or less, and particularly preferably 12,000 or less. When the Mw of the resin is within the above range, a resulting resist film is good in heat resistance and developability.

The ratio (Mw/Mn) of Mw to the number average molecular weight (Mn) of the resin as a base resin as determined by GPC relative to standard polystyrene is usually 1 or more and 5 or less, preferably 1 or more and 3 or less, and more preferably 1 or more and 2 or less.

The Mw and the Mn of a resin in the present description are values measured using gel permeation chromatography (GPC) under the following conditions.
GPC column: two G2000HXL, one G3000HXL, one G4000HXL (all manufactured by Tosoh Corporation)
Column temperature: 40° C.
Elution solvent: tetrahydrofuran
Flow rate: 1.0 mL/min
Sample concentration: 1.0% by mass
Amount of sample injected: 100 μL
Detector: differential refractometer
Standard substance: monodisperse polystyrene

The content of the resin is preferably 70% by mass or more, more preferably 75% by mass or more, and still more preferably 80% by mass or more based on the total solid content of the radiation-sensitive resin composition.

### <Other Resins>

The radiation-sensitive resin composition of the present embodiment may contain a resin having a higher content rate by mass of fluorine atoms than the base resin as described above (hereinafter also referred as “high fluorine-containing resin”) as other resin. When the radiation-sensitive resin composition contains the high fluorine-containing resin, the high-fluorine-containing resin can be localized in the surface layer of a resist film compared to the base resin, and as a result, the state of the surface of the resist film can be controlled to a desired state.

The high fluorine-containing resin preferably has, for example, one or more of the structural unit A through the structural unit E in the above-described base resin, as necessary, and have a structural unit represented by the following formula (f0) (hereinafter also referred to as “structural unit F”).

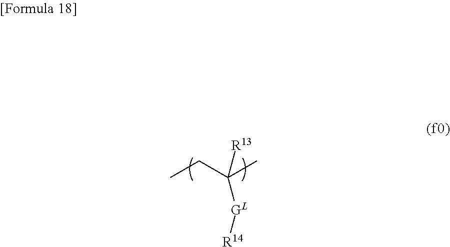

In the above formula (f0), R¹³ is a hydrogen atom, a methyl group, or a trifluoromethyl group. G^{L} is a single bond, an oxygen atom, a sulfur atom, —COO—, —SO₂ONH—, —CONH—, or —OCONH—. R¹⁴ is a monovalent fluorinated chain hydrocarbon group having 1 to 20 carbon atoms or a monovalent fluorinated alicyclic hydrocarbon group having 3 to 20 carbon atoms.

As the R¹³, a hydrogen atom and a methyl group are preferable from the viewpoint of the copolymerizability of a monomer that affords the structural unit F, and a methyl group is more preferable.

As the G^{L}, a single bond and —COO— are preferable from the viewpoint of the copolymerizability of a monomer that affords the structural unit F, and —COO— is more preferable.

Examples of the monovalent fluorinated chain hydrocarbon group having 1 to 20 carbon atoms represented by R¹⁴ include groups in which some or all of the hydrogen atoms in the linear or branched chain alkyl group having 1 to 20 carbon atoms are substituted with fluorine atoms.

Examples of the monovalent fluorinated alicyclic hydrocarbon group having 3 to 20 carbon atoms represented by R¹⁴ include monovalent fluorinated alicyclic hydrocarbon groups having 3 to 20 carbon atoms in which some or all of the hydrogen atoms of a mono- or polycyclic hydrocarbon group are substituted with fluorine atoms.

As the R¹⁴, fluorinated chain hydrocarbon groups are preferable, fluorinated alkyl groups are more preferable, and a 2,2,2-trifluoroethyl group, a 1,1,1,3,3,3-hexafluoropropyl group, a 5,5,5-trifluoro-1,1-diethylpentyl group, and a 1,1,1,2,2,3,3-heptafluoro-6-methylheptan-4-yl group are still more preferable.

When the high fluorine-containing resin contains the structural unit F, the content of the structural unit F is preferably 20 mol % or more, more preferably 30 mol % or more, and still more preferably 40 mol % or more based on all structural units constituting the high fluorine-containing resin. The content is preferably 100 mol % or less, more preferably 95 mol % or less, and still more preferably 90 mol % or less. When the content of the structural unit F is adjusted to within the above range, the content by mass of fluorine atoms in the high fluorine-containing resin can more appropriately be adjusted and the localization in the surface layer of a resist film can be further promoted.

The high fluorine-containing resin may have other structural units in addition to the structural unit F. Examples of such other structural units include a structural unit G having an alcoholic hydroxy group and having a fluorinated hydrocarbon group bonded to the carbon atom to which the alcoholic hydroxy group is bonded; and a structural unit H containing at least one selected from the group consisting of an iodine atom and a bromine atom. The structural unit H more preferably contains an aromatic ring structure substituted with an iodine atom.

When the high fluorine-containing resin contains the structural unit G, the content of the structural unit G is preferably 10 mol % or more, more preferably 15 mol % or more, and still more preferably 20 mol % or more based on all structural units constituting the high fluorine-containing resin. The content is preferably 70 mol % or less, more preferably 60 mol % or less, and still more preferably 50 mol % or less. When the high fluorine-containing resin contains the structural unit H, the content of the structural unit H is preferably 1 mol % or more, more preferably 3 mol % or more, and still more preferably 5 mol % or more based on all structural units constituting the high fluorine-containing resin. The content is preferably 40 mol % or less, more preferably 30 mol % or less, and still more preferably 20 mol % or less. When the contents of the structural unit G and the structural unit H are adjusted to within the above ranges, the surface of a resist film can be controlled to a desired state.

The Mw of the high fluorine-containing resin is preferably 1,000 or more, more preferably 2,000 or more, still more preferably 3,000 or more, and particularly preferably 5,000 or more. The Mw is preferably 50,000 or less, more preferably 30,000 or less, still more preferably 20,000 or less, and particularly preferably 15,000 or less.

The Mw/Mn of the high fluorine-containing resin is usually 1 or more, and more preferably 1.1 or more. The Mw/Mn is usually 5 or less, preferably 3 or less, more preferably 2.5 or less, and still more preferably 2.2 or less.

The content of the high fluorine-containing resin is preferably 1 part by mass or more, more preferably 2 parts by mass or more, and still more preferably 3 parts by mass or more based on 100 parts by mass of the base resin (when a radiation-sensitive acid generating resin and a resin are contained, the total amount of them is taken as the basis). The content is preferably 20 parts by mass or less, more preferably 15 parts by mass or less, and still more preferably 10 parts by mass or less. When the content of the high fluorine-containing resin is adjusted to within the above range, the high fluorine-containing resin can be more effectively localized in the surface layer of a resist film, and as a result, the elusion of a top portion of a pattern is controlled during development and the rectangularity of a pattern can be enhanced. The radiation-sensitive resin composition may contain one type or two or more types of high fluorine-containing resins.

### (Method for Synthesizing High Fluorine-Containing Resin)

The high fluorine-containing resin can be synthesized by the same method as the method for synthesizing a base resin described above.

### <Onium Salt>

The onium salt is a component that contains an organic acid anion moiety and an onium cation moiety and generates an acid through exposure to light. When at least part of the onium cation moiety in the onium salt contains an aromatic ring structure having a fluorine atom, it is possible to achieve increased sensitivity due to improvement in acid generation efficiency and exhibition of CDU performance due to acid diffusion controllability.

While the mode of incorporation of the onium salt in the radiation-sensitive resin composition is not particularly limited, the onium salt is at least one member selected from the group consisting of a radiation-sensitive acid generating resin containing a structural unit having the organic acid anion moiety and the onium cation moiety, a radiation-sensitive acid generator containing the organic acid anion moiety and the onium cation moiety, and an acid diffusion controlling agent containing the organic acid anion moiety and the onium cation moiety and generating an acid having a pKa higher than that of an acid to be generated from the radiation-sensitive acid generator through irradiation with radiation. Differences between these functions will be described below.

The acid generated through the exposure to the onium salt is considered to have two functions in the radiation-sensitive resin composition depending on the strength of the acid. A first function may be a function that an acid generated through exposure to light dissociates the acid-dissociable group of the resin to generate a carboxy group or the like. An onium salt having the first function is referred to as a radiation-sensitive acid generator. Examples of a second function include a function that controls, by salt exchange, the diffusion of the acid generated from the radiation-sensitive acid generator in the unexposed area without substantially dissociating the acid-dissociable group of the resin under a pattern formation condition using the radiation-sensitive resin composition. An onium salt having the second function is referred to as an acid diffusion controlling agent. The acid generated from the acid diffusion controlling agent can be said to be an acid relatively weaker (acid having a higher pKa) than the acid to be generated from the radiation-sensitive acid generator. Whether an onium salt functions as a radiation-sensitive acid generator or an acid diffusion controlling agent depends on the energy required for dissociating the acid-dissociable group of the resin and the acidity of the onium salt. The mode of incorporation of the radiation-sensitive acid generator in the radiation-sensitive resin composition may be a mode in which the onium salt structure is present alone as a compound (released from a polymer), a mode in which the onium salt structure is incorporated as a part of a polymer, or both of these modes. A form in which an onium salt structure is incorporated as a part of a polymer is particularly referred to as a radiation-sensitive acid generating resin.

When the radiation-sensitive resin composition contains the radiation-sensitive acid generator or a radiation-sensitive acid generating resin, the polarity of the resin in an exposed area increases, and as a result, when the developer is an aqueous alkaline solution, the resin in the exposed area is soluble in the developer, and on the other hand, when the developer is an organic solvent, the resin in the exposed area is hardly soluble in the developer.

When the radiation-sensitive resin composition contains the acid diffusion controlling agent, diffusion of an acid in an unexposed area can be controlled, and a resist pattern further superior in pattern developability and CDU performance can be formed.

In the radiation-sensitive resin composition, it is just required that the onium cation moiety in at least one member selected from the group consisting of the radiation-sensitive acid generating resin, the radiation-sensitive acid generator, and the acid diffusion controlling agent contains an aromatic ring structure having a fluorine atom.

Even in any mode of incorporation of the onium salt, the organic acid anion moiety preferably has at least one type of anion selected from the group consisting of a sulfonate anion, a carboxylate anion, and a sulfonimide anion. The onium cation is preferably at least one selected from the group consisting of a sulfonium cation and an iodonium cation. When the onium salt has a combination of these structures, the above-described function can be efficiently exhibited.

Examples of the acid to be generated through the exposure include acids that generate sulfonic acid, carboxylic acid, and sulfonimide through exposure with correspondence to the organic acid anion.

Examples of the onium salt that affords a sulfonic acid through exposure to light include:
(1) a compound in which one or more fluorine atoms or fluorinated hydrocarbon groups are bonded to a carbon atom adjacent to a sulfonic acid anion; and
(2) a compound in which neither fluorine atom nor fluorinated hydrocarbon group is bonded to a carbon atom adjacent to a sulfonic acid anion.

Examples of the onium salt that affords a carboxylic acid through exposure to light include:
(3) a compound in which one or more fluorine atoms or fluorinated hydrocarbon groups are bonded to a carbon atom adjacent to a carboxylic acid anion,
(4) a compound in which neither fluorine atom nor fluorinated hydrocarbon group is bonded to a carbon atom adjacent to a carboxylic acid anion.

Among them, as the radiation-sensitive acid generator or the radiation-sensitive acid generating resin, those corresponding to the above (1) are preferable. As the acid diffusion controlling agent, those corresponding to the above (2), (3), or (4) are preferable, and those corresponding to the above (2) or (4) are particularly preferable.

### <Radiation-Sensitive Acid Generator>

The radiation-sensitive resin composition preferably further includes a radiation-sensitive acid generator that generates an acid having a pKa lower than that of the acid generated from the acid diffusion controlling agent by irradiation with radiation (exposure to light). When the radiation-sensitive resin composition contains the radiation-sensitive acid generator, the acid generated by exposure to light dissociates the acid-dissociable group of the resin to generate a carboxy group or the like. As a result, the polarity of the resin in the exposed area increases, so that in the case of development with an aqueous alkaline solution, the resin in the exposed area is soluble in the developer, whereas in the case of development with an organic solvent, the resin in the exposed area is hardly soluble in the developer.

The radiation-sensitive acid generator preferably contains an organic acid anion moiety and an onium cation moiety. The organic acid anion moiety preferably has at least one type of anion selected from the group consisting of a sulfonate anion and a sulfonimide anion. Examples of the acid generated by exposure to light include a sulfonic acid and a sulfonimide corresponding to the organic acid anion moiety. The organic acid anion moiety preferably contains an iodine-substituted aromatic ring structure.

In particular, a compound in which one or more fluorine atoms or fluorinated hydrocarbon groups are bonded to a carbon atom adjacent to a sulfonate anion can be suitably employed as a radiation-sensitive acid generator that affords a sulfonic acid by exposure to light.

The radiation-sensitive acid generator is preferably represented by the following formula (A-1) or (A-2).

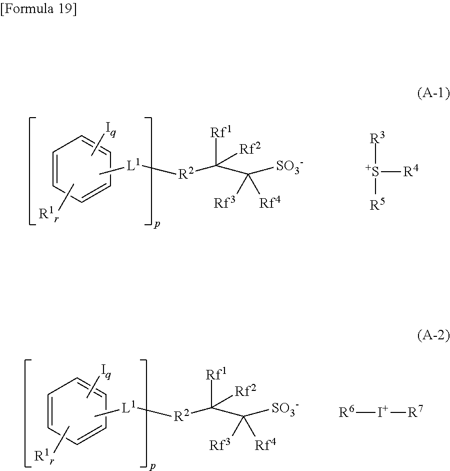

In the formulas (A-1) and (A-2), L¹ is a single bond, an ether linkage, an ester linkage, or an alkylene group having 1 to 6 carbon atoms and optionally containing an ether linkage or an ester linkage. The alkylene group may be linear, branched, or cyclic.

R¹ is a hydroxy group, a carboxy group, a fluorine atom, a chlorine atom, a bromine atom, or an amino group; or is an alkyl group having 1 to 20 carbon atoms, an alkoxy group having 1 to 20 carbon atoms, an alkoxycarbonyl group having 2 to 10 carbon atoms, an acyloxy group having 2 to 20 carbon atoms, or an alkylsulfonyloxy group having 1 to 20 carbon atoms, each optionally containing a fluorine atom, a chlorine atom, a bromine atom, a hydroxy group, an amino group, or an alkoxy group having 1 to 10 carbon atoms; or is —NR⁸—C(═O)—R⁹ or —NR⁸—C(═O)—O—R⁹, wherein R⁸ is a hydrogen atom or an alkyl group having 1 to 6 carbon atoms and optionally containing a halogen atom, a hydroxy group, an alkoxy group having 1 to 6 carbon atoms, an acyl group having 2 to 6 carbon atoms, or an acyloxy group having 2 to 6 carbon atoms, and R⁹ is an alkyl group having 1 to 16 carbon atoms, an alkenyl group having 2 to 16 carbon atoms, or an aryl group having 6 to 12 carbon atoms and optionally contains a halogen atom, a hydroxy group, an alkoxy group having 1 to 6 carbon atoms, an acyl group having 2 to 6 carbon atoms, or an acyloxy group having 2 to 6 carbon atoms. The alkyl group, alkoxy group, alkoxycarbonyl group, acyloxy group, acyl group, and alkenyl group may be linear, branched, or cyclic.

Among them, R¹ is preferably a hydroxy group, —NR⁸—C(═O)—R⁹, a fluorine atom, a chlorine atom, a bromine atom, a methyl group, a methoxy group, or the like.

R² is a single bond or a divalent linking group having 1 to 20 carbon atoms when p is 1, and is a trivalent or tetravalent linking group having 1 to 20 carbon atoms when p is 2 or 3, and the linking groups may contain an oxygen atom, a sulfur atom, or a nitrogen atom.

Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf² may be combined to form a carbonyl group. In particular, both Rf³ and Rf⁴ are preferably fluorine atoms.

R³, R⁴, R⁵, R⁶, and R⁷ are each independently a monovalent hydrocarbon group having 1 to 20 carbon atoms and optionally containing a hetero atom. Any two of R³, R⁴, and R⁵ may be bonded to each other to form a ring together with the sulfur atom to which they are bonded. The monovalent hydrocarbon group may be linear, branched, or cyclic, and examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be replaced by a hydroxy group, a carboxy group, a halogen atom, a cyano group, an amide group, a nitro group, a mercapto group, a sultone group, a sulfone group, or a sulfonium salt-containing group, and some of the carbon atoms of these groups may be replaced by an ether linkage, an ester linkage, a carbonyl group, a carbonate group, or a sulfonic acid ester linkage.

p is an integer satisfying 1≤p≤3. q and r are integers satisfying 0≤q≤5, 0≤r≤3, and 0≤q≤r 5. q is preferably an integer satisfying 1≤q≤3, and more preferably 2 or 3. r is preferably an integer satisfying 0≤r≤2.

Examples of the organic acid anion moiety of the radiation-sensitive acid generators represented by the formulas (A-1) and (A-2) include, but are not limited to, those shown below. Organic acid anion moieties having no iodine-substituted aromatic ring structure that can be suitably employed include structures in which the iodine atoms in the formulas shown below are replaced by an atom or group other than an iodine atom such as a hydrogen atom or other substituent.

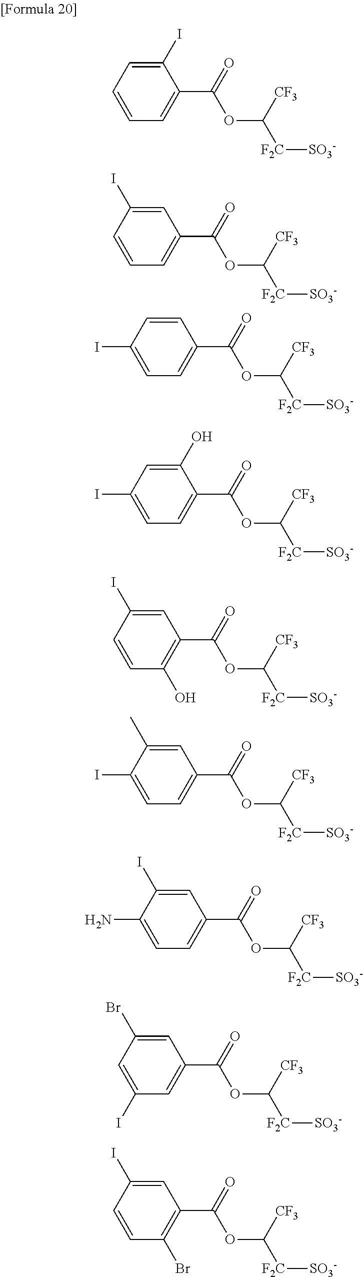

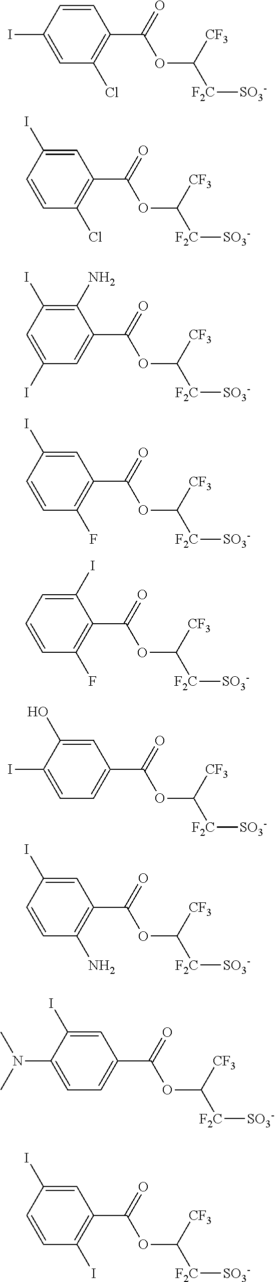

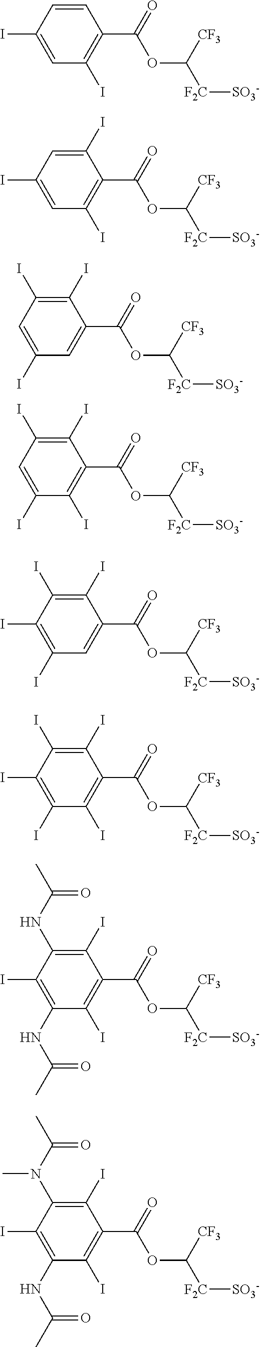

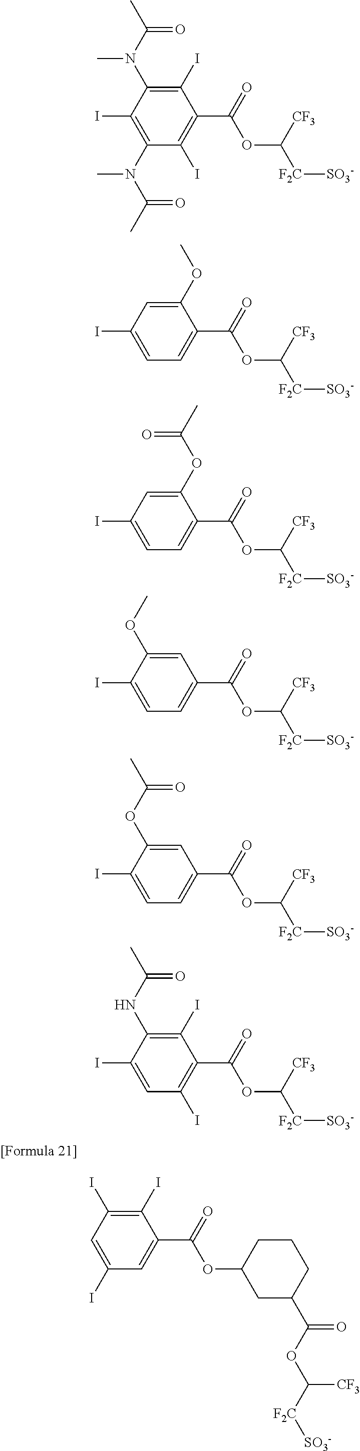

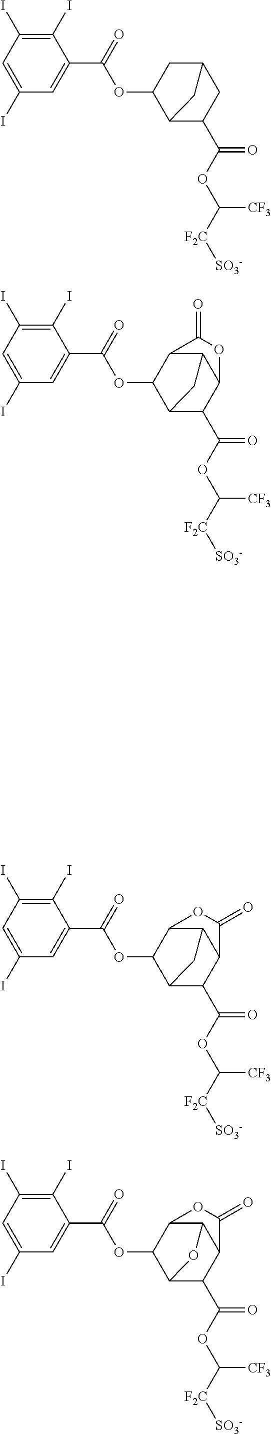

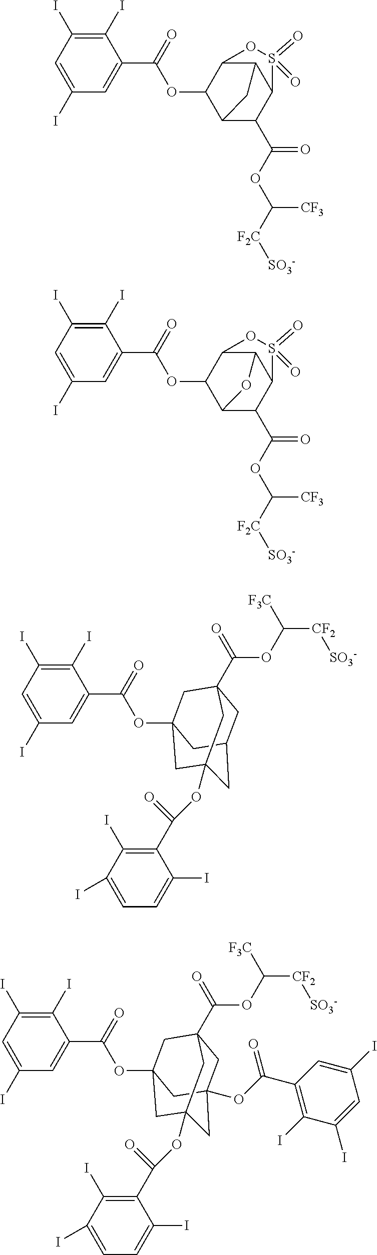

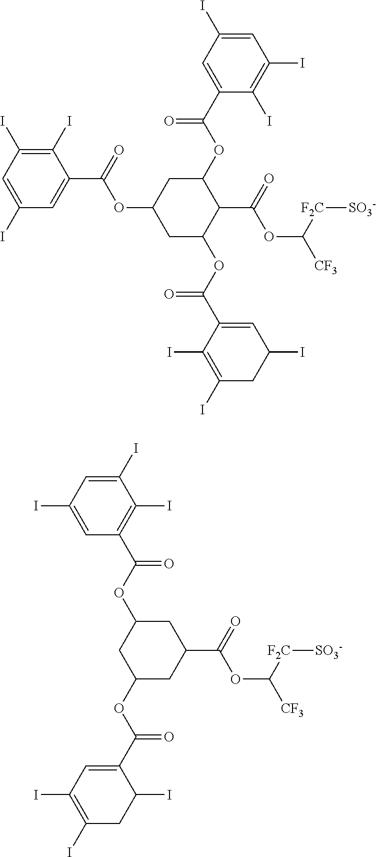

Examples of the organic acid anion moiety of the radiation-sensitive acid generator represented by the formulas (A-1) and (A-2) and examples of the organic acid anion moiety corresponding to neither the formula (A-1) nor the formula (A-2) are shown below.

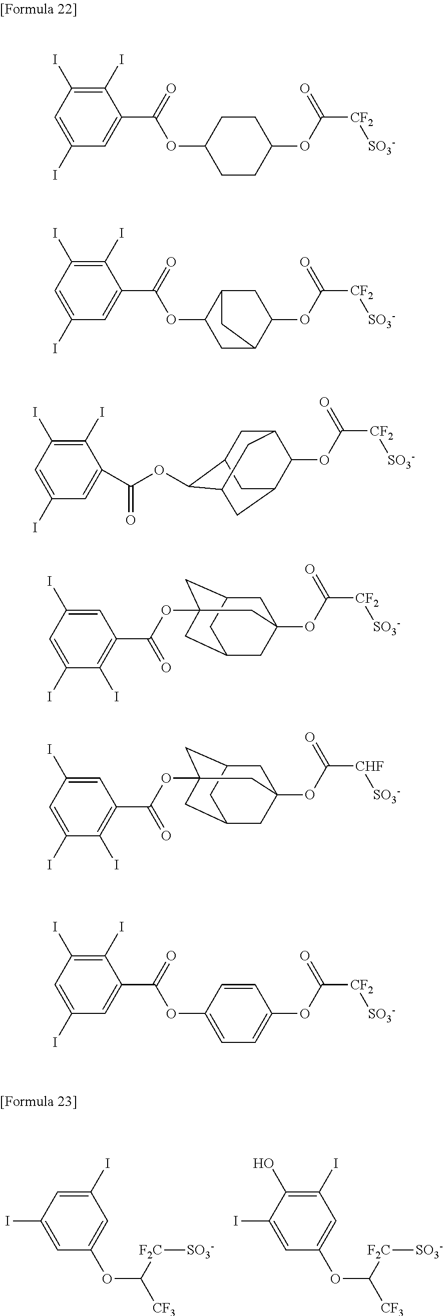

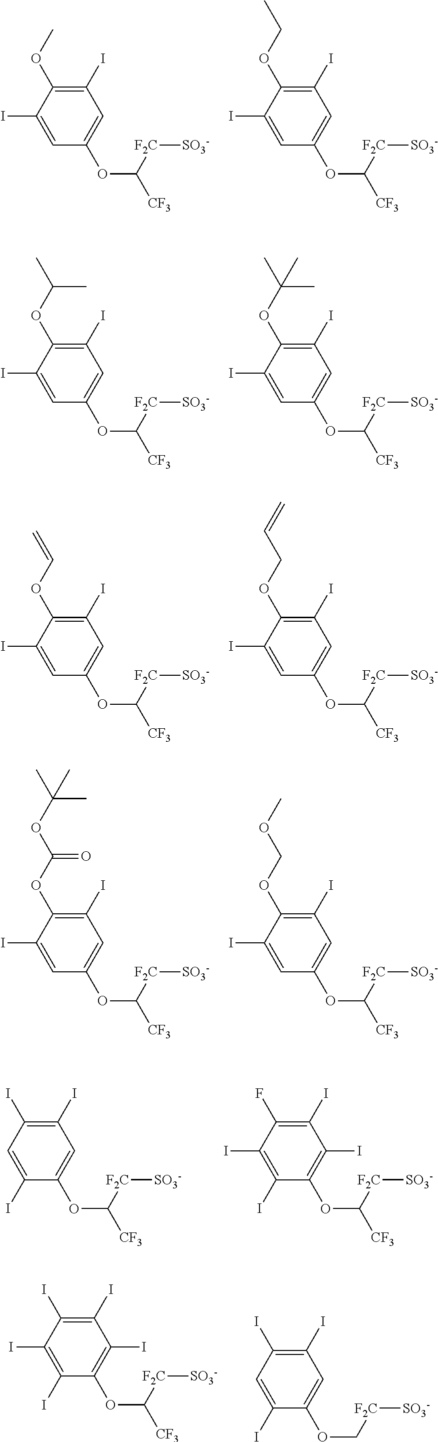

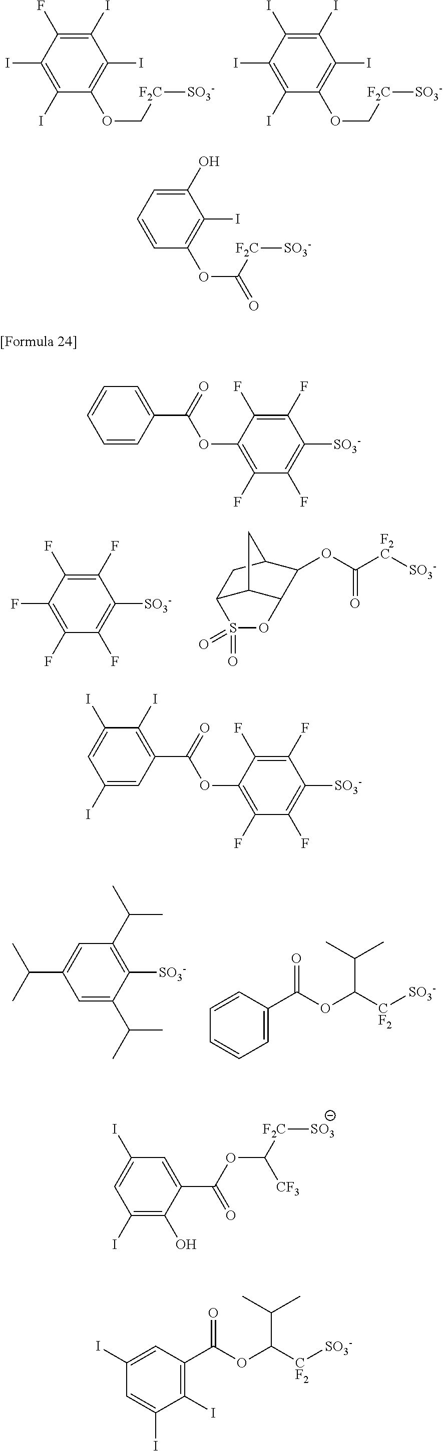

As the onium cation moiety in the radiation-sensitive acid generator represented by the formula (A-1), the structures disclosed as the onium cation moiety in the structural unit B that can be contained in the resin can be suitably employed. Among them, an onium cation containing an aromatic ring structure having a fluorine atom is preferable, an onium cation represented by the formula (Q-1) is more preferable, a sulfonium cation having two or more aromatic ring structures having a fluorine atom is still more preferable, and a sulfonium cation having three aromatic ring structures having a fluorine atom is particularly preferable.

These radiation-sensitive acid generators may be used singly, or two or more thereof may be used in combination. The lower limit of the content of the radiation-sensitive acid generator is preferably 0.5 parts by mass, more preferably 1 part by mass, still more preferably 1.5 parts by mass, and particularly preferably 2 parts by mass per 100 parts by mass of the base resin. The upper limit of the content is preferably 20 parts by mass or less, more preferably 18 parts by mass or less, still more preferably 15 parts by mass or less, and particularly preferably 12 parts by mass or less based on 100 parts by mass of the resin. This makes it possible to exhibit superior sensitivity or CDU performance when forming a resist pattern.

### <Acid Diffusion Controlling Agent>

The acid diffusion controlling agent contains an organic acid anion moiety and an onium cation moiety and generates an acid having a higher pKa than an acid to be generated from the radiation-sensitive acid generator through irradiation with radiation. Examples of such an organic acid anion moiety include carboxylic acids. The organic acid anion moiety preferably contains an iodine-substituted aromatic ring structure. The acid diffusion controlling agent is preferably represented by the following formula (S-1) or (S-2).

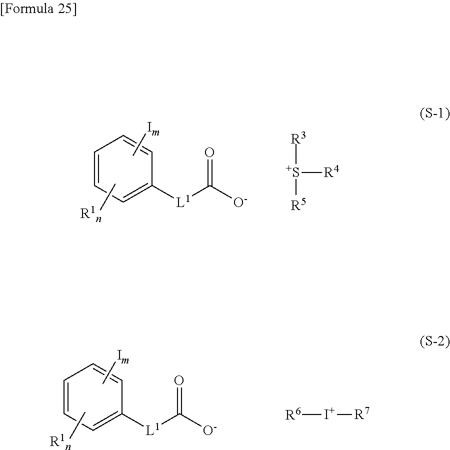

In the formulas (S-1) and (S-2), R¹ is a hydrogen atom, a hydroxy group, a fluorine atom, a chlorine atom, an amino group, a nitro group, or a cyano group; or an alkyl group having 1 to 6 carbon atoms, an alkoxy group having 1 to 6 carbon atoms, an acyloxy group having 2 to 6 carbon atoms, or an alkylsulfonyloxy group having 1 to 4 carbon atoms, which may be substituted with a halogen atom; or —NR^{1A}—C(═O)—R^{1B} or —NR^{1A}—C(═O)—O—R^{1B}. R^{1A} is a hydrogen atom or an alkyl group having 1 to 6 carbon atoms, and R^{1B} is an alkyl group having 1 to 6 carbon atoms or an alkenyl group having 2 to 8 carbon atoms.

The alkyl group having 1 to 6 carbon atoms may be linear, branched, or cyclic, and examples thereof include a methyl group, an ethyl group, a n-propyl group, an isopropyl group, a cyclopropyl group, a n-butyl group, an isobutyl group, a sec-butyl group, a tert-butyl group, a cyclobutyl group, a n-pentyl group, a cyclopentyl group, a n-hexyl group, and a cyclohexyl group. Examples of the alkyl moiety of the alkoxy group having 1 to 6 carbon atoms, the acyloxy group having 2 to 7 carbon atoms, and the alkoxycarbonyl group having 2 to 7 carbon atoms include those the same as the examples of the alkyl group described above, and examples of the alkyl moiety of the alkylsulfonyloxy group having 1 to 4 carbon atoms include those having 1 to 4 carbon atoms among the examples of the alkyl group described above. The alkenyl group having 2 to 8 carbon atoms may be linear, branched, or cyclic, and examples thereof include a vinyl group, a 1-propenyl group, and a 2-propenyl group. Among them, a fluorine atom, a chlorine atom, a hydroxy group, an amino group, an alkyl group having 1 to 3 carbon atoms, an alkoxy group having 1 to 3 carbon atoms, an acyloxy group having 2 to 4 carbon atoms, —NR^{1A}—C(═O)—R^{1B}, and —NR^{1A}—C(═O)—O—R^{1B} are preferable as R¹.

R³, R⁴, R⁵, R⁶, and R⁷ are each independently a monovalent hydrocarbon group having 1 to 20 carbon atoms and optionally containing a hetero atom. When the onium cation moiety of the acid diffusion controlling agent has a fluorine atom, at least one of R³, R⁴, and R⁵ contains one or more fluorine atoms, and at least one of R⁶ and R⁷ contains one or more fluorine atoms. Any two of R³, R⁴, and R⁵ may be bonded to each other to form a ring together with the sulfur atom to which they are bonded. The monovalent hydrocarbon group may be linear, branched, or cyclic, and examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be replaced by a hydroxy group, a carboxy group, a halogen atom, a cyano group, an amide group, a nitro group, a mercapto group, a sultone group, a sulfone group, or a sulfonium salt-containing group, and some of the carbon atoms of these groups may be replaced by an ether linkage, an ester linkage, a carbonyl group, a carbonate group, or a sulfonic acid ester linkage.

L¹ is a single bond or a divalent linking group having 1 to 20 carbon atoms, and may contain an ether linkage, a carbonyl group, an ester linkage, an amide linkage, a sultone ring, a lactam ring, a carbonate linkage, a halogen atom, a hydroxy group, or a carboxy group.

m and n are integers satisfying 0≤m≤5, 0≤n≤3, and 0≤m+n≤5, and preferably integers satisfying 1≤m≤3 and 0≤n≤2.

Examples of the organic acid anion moiety of the acid diffusion controlling agent represented by the above formula (S-1) or (S-2) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are replaced by an atom or group other than an iodine atom such as a hydrogen atom or other substituent.

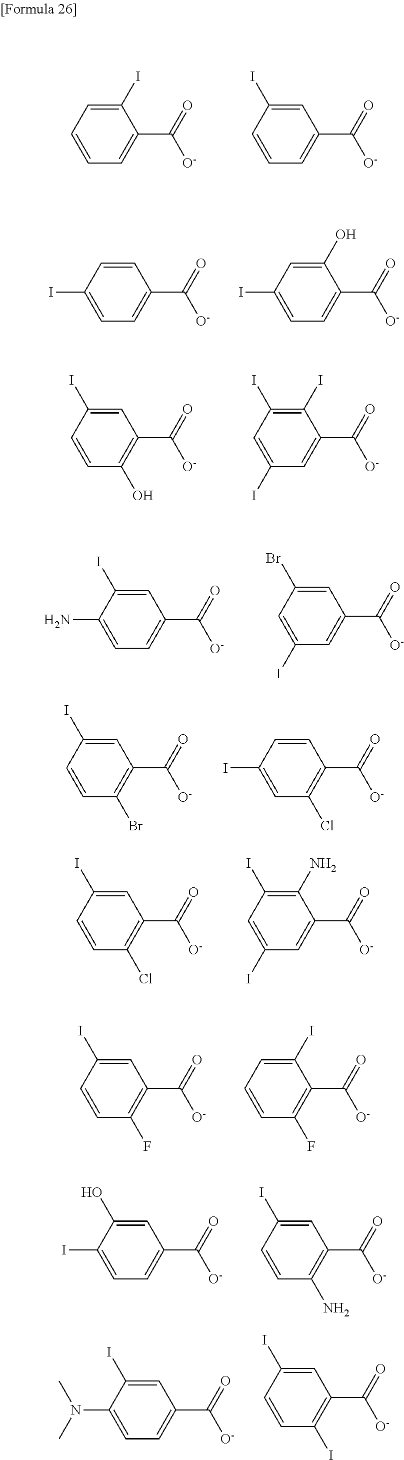

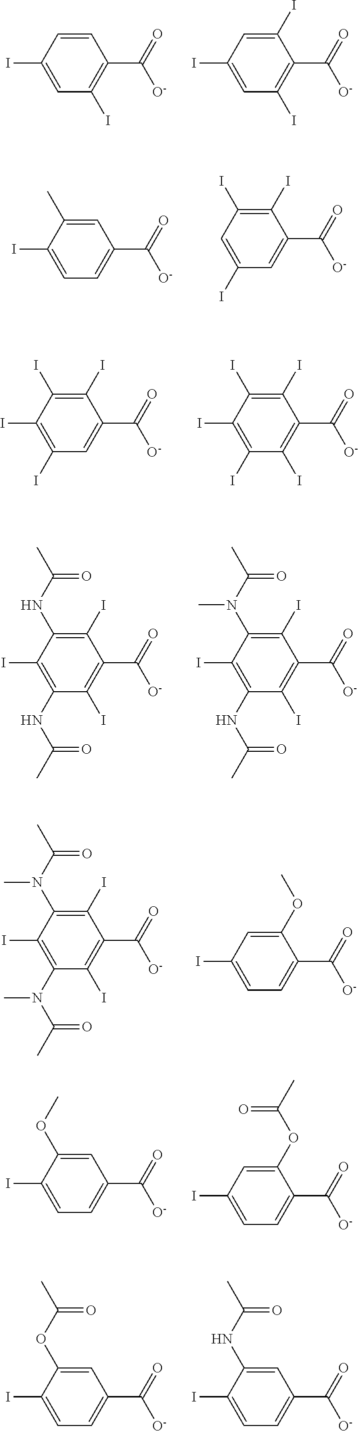

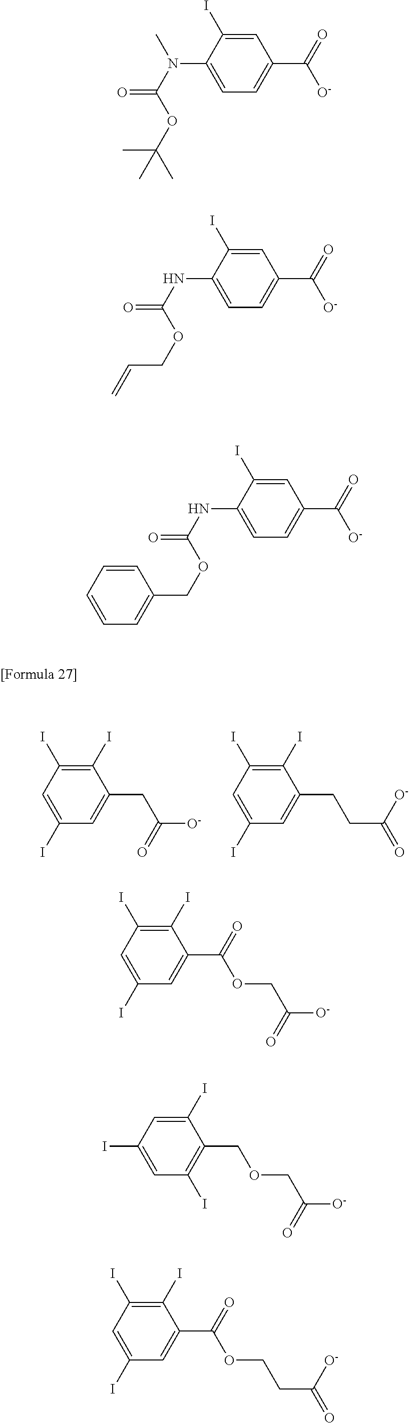

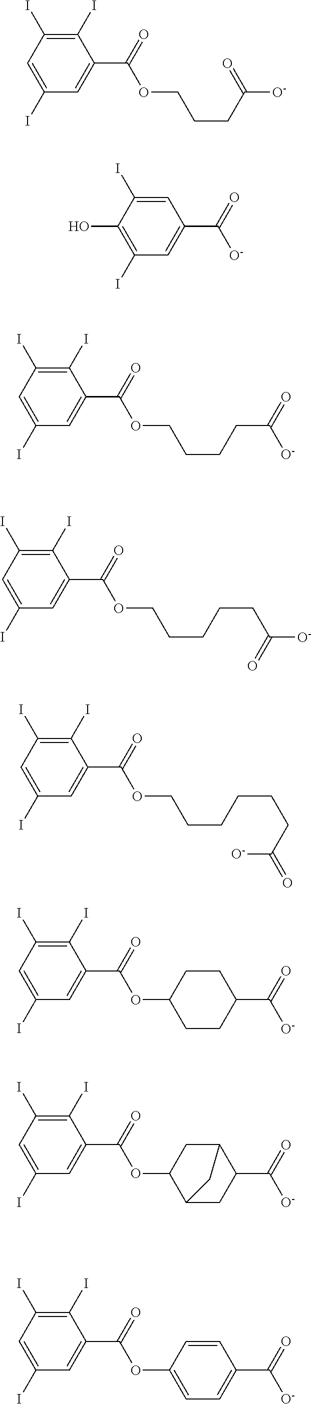

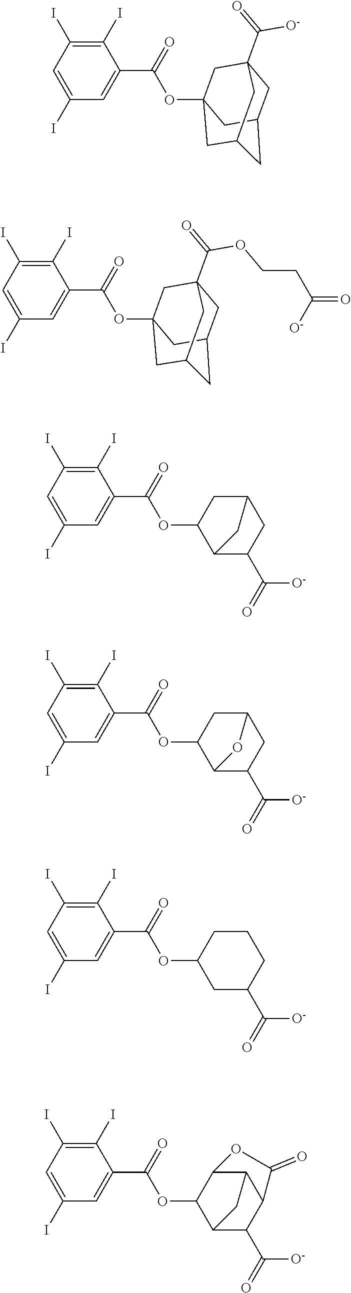 [SMILES: O=C(OC12CC3CC(C1)CC(C(=O)[O-])(C3)C2)c1cc(I)cc(I)c1I ; O=C([O-])CCOC(=O)C12CC3CC(CC(OC(=O)c4cc(I)cc(I)c4I)(C3)C1)C2 ; O=C(OC1CC2CC(C(=O)[O-])C1C2)c1cc(I)cc(I)c1I ; O=C(OC1CC2CC(C(=O)[O-])C1O2)c1cc(I)cc(I)c1I ; O=C(OC1CCCC(C(=O)[O-])C1)c1cc(I)cc(I)c1I ; O=C(OC1C2CC3C1OC(=O)C3C2C(=O)[O-])c1cc(I)cc(I)c1I]

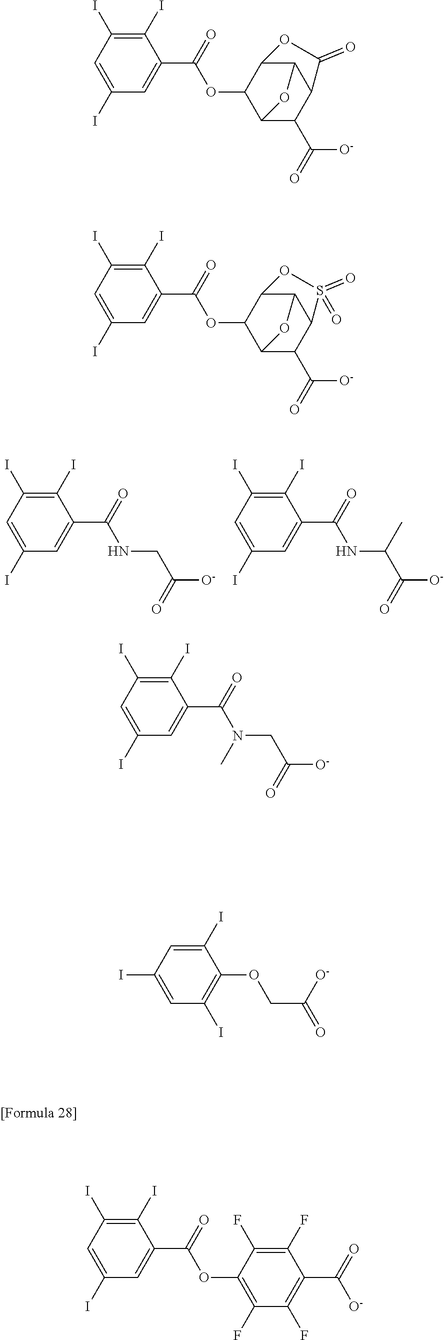

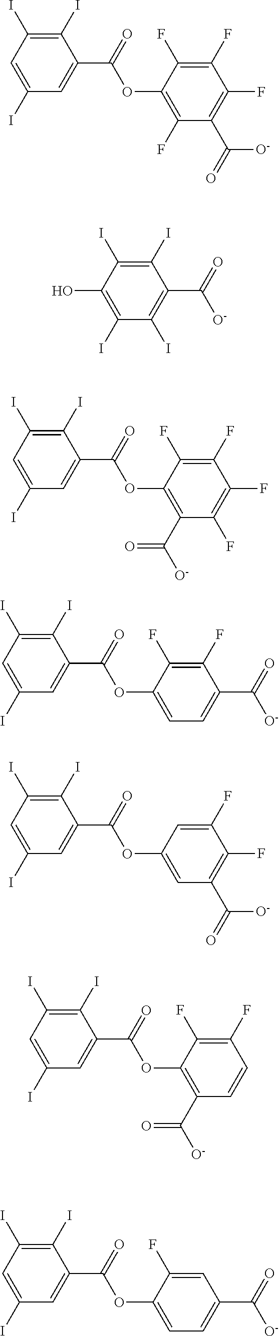

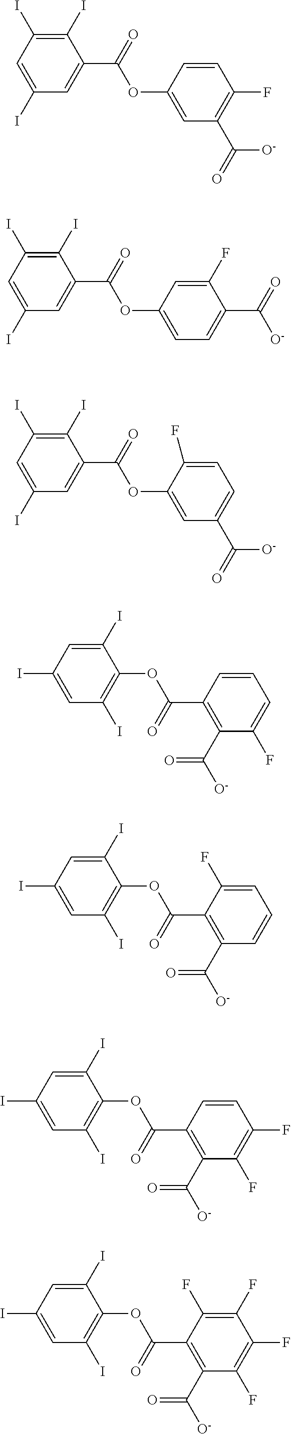

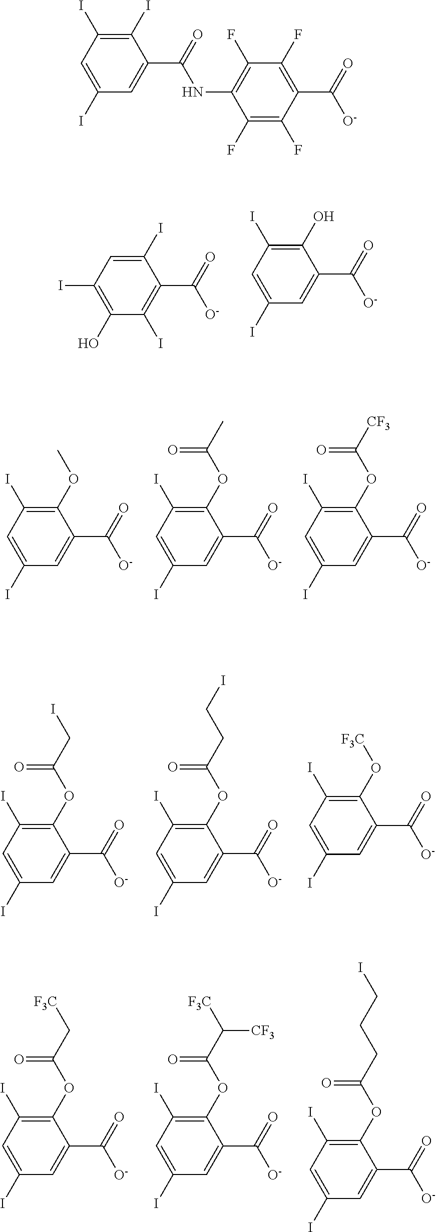

As the onium cation moieties in the acid diffusion controlling agents represented by the formulas (S-1) and (S-2), the onium cation moiety in the structural unit B of the radiation-sensitive acid generating resin can be suitably employed. Among them, an onium cation containing an aromatic ring structure having a fluorine atom is preferable, an onium cation represented by the formula (Q-1) is more preferable, a sulfonium cation having two or more aromatic ring structures having a fluorine atom is still more preferable, and a sulfonium cation having three aromatic ring structures having a fluorine atom is particularly preferable.

The acid diffusion controlling agents represented by the formulas (S-1) and (S-2) can also be synthesized by a known method, particularly by a salt exchange reaction. A known acid diffusion controlling agent may also be used as long as the effect of the present invention is not impaired.

These acid diffusion controlling agents may be used singly, or two or more thereof may be used in combination. The content of the acid diffusion controlling agent is preferably 10% by mass or more, more preferably 25% by mass or more, and still more preferably 40% by mass or more based on the content of the radiation-sensitive acid generator (when a radiation-sensitive acid generating resin is contained, the total amount with the content of the structural unit B in 100 parts by mass of the radiation-sensitive acid generating resin is taken as the basis). The content is preferably 500% by mass or less, more preferably 200% by mass or less, and still more preferably 100% by mass or less. This makes it possible to exhibit superior sensitivity or CDU performance when forming a resist pattern.

### <Solvent>

The radiation-sensitive resin composition according to the present embodiment contains a solvent. The solvent is not particularly limited as long as it is a solvent capable of dissolving or dispersing at least a base resin (the radiation-sensitive acid generating resin and at least one of the resins) and additives which are contained as desired.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
monoalcohol-based solvents having 1 to 18 carbon atoms, such as iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
polyhydric alcohol-based solvents having 2 to 18 carbon atoms, such as ethylene glycol, 1,2-propylene glycol, 2-methyl-2,4-pentanediol, 2,5-hexanediol, diethylene glycol, dipropylene glycol, triethylene glycol, and tripropylene glycol; and
partially etherized polyhydric alcohol-based solvents in which some of the hydroxy groups of the polyhydric alcohol-based solvent are etherized.

Examples of the ether-based solvent include:
dialkyl ether-based solvents, such as diethyl ether, dipropyl ether, and dibutyl ether;
cyclic ether-based solvents, such as tetrahydrofuran and tetrahydropyran;
aromatic ring-containing ether-based solvents, such as diphenyl ether and anisole (methyl phenyl ether); and
etherized polyhydric alcohol-based solvents in which the hydroxy groups of the polyhydric alcohol-based solvent are etherized.

Examples of the ketone-based solvent include chain ketone-based solvents, such as acetone, butanone, and methyl-iso-butyl ketone;
cyclic ketone-based solvents, such as cyclopentanone, cyclohexanone, and methylcyclohexanone; and
2,4-pentanedione, acetonylacetone, and acetophenone.

Examples of the amide-based solvent include cyclic amide-based solvents, such as N,N′-dimethylimidazolidinone and N-methylpyrrolidone; and
chain amide-based solvents, such as N-methylformamide, N,N-dimethylformamide, N,N-diethylformamide, acetamide, N-methylacetamide, N,N-dimethylacetamide, and N-methylpropionamide.

Examples of the ester-based solvent include:
monocarboxylic acid ester-based solvents, such as n-butyl acetate and ethyl lactate;
polyhydric alcohol partial ether acetate-based solvents, such as diethylene glycol mono-n-butyl ether acetate, propylene glycol monomethyl ether acetate, and dipropylene glycol monomethyl ether acetate;
lactone-based solvents, such as γ-butyrolactone and valerolactone;
carbonate-based solvents, such as diethyl carbonate, ethylene carbonate, and propylene carbonate; and
polyvalent carboxylic acid diester-based solvents, such as propylene glycol diacetate, methoxytriglycol acetate, diethyl oxalate, ethyl acetoacetate, ethyl lactate, and diethyl phthalate.

Examples of the hydrocarbon-based solvent include:
aliphatic hydrocarbon-based solvents, such as n-hexane, cyclohexane, and methylcyclohexane; and
aromatic hydrocarbon-based solvents, such as benzene, toluene, di-iso-propylbenzene, and n-amylnaphthalene.

Among them, ester-based solvents and ketone-based solvents are preferable, polyhydric alcohol partial ether acetate-based solvents, cyclic ketone-based solvents, and lactone-based solvents are more preferable, and propylene glycol monomethyl ether acetate, cyclohexanone, and γ-butyrolactone are still more preferable. The radiation-sensitive resin composition may contain one or two or more solvents.

### <Other Optional Components>

The radiation-sensitive resin composition may contain other optional components in addition to the components described above. Examples of the other optional components include a crosslinking agent, a localization enhancing agent, a surfactant, an alicyclic backbone-containing compound, and a sensitizer. Such other optional components may be used singly, or two or more types thereof may be used in combination.

### <Method for Preparing Radiation-Sensitive Resin Composition>

The radiation-sensitive resin composition can be prepared, for example, by mixing a base resin (at least one of a radiation-sensitive acid generating resin and a resin) and a solvent, and if necessary, another optional component at a prescribed ratio. The radiation-sensitive resin composition is preferably filtered through, for example, a filter having a pore size of about 0.05 μm after mixing. The solid content concentration of the radiation-sensitive resin composition is usually 0.1% by mass to 50% by mass, preferably 0.5% by mass to 30% by mass, and more preferably 1% by mass to 20% by mass.

### <Pattern Formation Method>

The pattern formation method according to the present embodiment includes:
step (1) of applying the radiation-sensitive resin composition directly or indirectly to a substrate to form a resist film (hereinafter also referred to as “resist film formation step”);
step (2) of exposing the resist film to light (hereinafter also referred to as “exposure step”); and
step (3) of developing the exposed resist film (hereinafter also referred to as “development step”).

In accordance with this pattern formation method, a high-quality resist pattern can be formed because of the use of the radiation-sensitive resin composition superior in sensitivity and CDU performance in an exposure step. Hereinafter, the steps will be described.

### [Resist Film Forming Step]

In this step (step (1)), a resist film is formed from the radiation-sensitive resin composition. Examples of the substrate on which the resist film is formed include conventionally known substrates such as a silicon wafer, silicon dioxide, and a wafer coated with aluminum. An organic or inorganic antireflective film disclosed in, for example, JP-B-6-12452 or JP-A-59-93448 may be formed on the substrate. Examples of a method for applying the composition include spin coating, cast coating, and roll coating. After the application, prebaking (PB) may be performed to volatilize the solvent in the coating film, as necessary. The PB temperature is usually 60° C. to 140° C., and preferably 80° C. to 120° C. The PB time is usually 5 seconds to 600 seconds, and preferably 10 seconds to 300 seconds. The thickness of the resist film to be formed is preferably 10 nm to 1,000 nm, and more preferably 10 nm to 500 nm.

In the case of performing immersion exposure, regardless of the presence or absence of a water repellent polymer additive such as the high fluorine-containing resin in the radiation-sensitive resin composition, a protective film for immersion insoluble in an immersion liquid may be provided on the formed resist film for the purpose of avoiding direct contact between the immersion liquid and the resist film. As the protective film for immersion, either a solvent-removable protective film that is to be removed by a solvent before the development step (see, for example, JP-A-2006-227632) or a developer-removable protective film that is to be removed simultaneously with the development in the development step (see, for example, WO 2005/069076 A1 and WO 2006/035790 A1) may be used. However, from the viewpoint of throughput, it is preferable to use a developer-removable protective film for immersion.

### [Exposure Step]

In this step (the step (2)), the resist film formed in the resist film forming step, namely the step (1), is irradiated with radiation through a photomask (as the case may be, through an immersion medium such as water) to be exposed. Examples of the radiation to be used for the exposure include an electromagnetic wave including visible ray, ultraviolet ray, far ultraviolet ray, extreme ultraviolet ray (EUV), X ray, and γ ray; an electron beam; and a charged particle radiation such as a ray. Among them, far ultraviolet ray, electron beam, and EUV are preferable, ArF excimer laser light (wavelength: 193 nm), KrF excimer laser light (wavelength: 248 nm), electron beam, and EUV are more preferable, and an electron beam and EUV having a wavelength of 50 nm or less, which are positioned as next-generation exposure technology, are still more preferable.

When the exposure is performed by immersion exposure, examples of the immersion liquid to be used include water and a fluorine-based inert liquid. The immersion liquid is preferably a liquid that is transparent to an exposure wavelength and has a temperature coefficient of refractive index as small as possible to minimize the distortion of an optical image projected onto the film. Particularly, when an exposure light source is ArF excimer laser light (wavelength: 193 nm), water is preferably used from the viewpoint of availability and ease of handling in addition to the above-described viewpoints. When water is used, an additive that reduces the surface tension of water and increases the surface activity may be added in a small proportion. This additive is preferably one that does not dissolve the resist film on a wafer and has negligible influence on an optical coating at an under surface of a lens. The water to be used is preferably distilled water.

After the exposure, post exposure baking (PEB) is preferably carried out to promote the dissociation of the acid-dissociable group of the resin or the like due to the acid generated from the radiation-sensitive acid generator through the exposure in the exposed area of the resist film. As a result of the PEB, there is produced a difference in solubility in the developer between the exposed area and the unexposed area. The PEB temperature is usually 50° C. to 180° C., and preferably 80° C. to 130° C. The PEB time is usually 5 seconds to 600 seconds, and preferably 10 seconds to 300 seconds.

### [Development Step]

In this step (the step (3)), the resist film exposed in the exposure step, namely the step (2), is developed. Thus, a prescribed resist pattern can be formed. In a common procedure, after the development, the film is washed with a rinsing liquid such as water or alcohol and dried.

Examples of the developer to be used for the development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, the aqueous TMAH solution is preferable, and a 2.38% by mass aqueous TMAH solution is more preferable.

In the case of organic solvent development, examples of the solvent include organic solvents such as hydrocarbon-based solvents, ether-based solvents, ester-based solvents, ketone-based solvents, and alcohol-based solvents, and solvents containing an organic solvent. Examples of the organic solvent include one type or two or more types of solvent among the solvents listed as the solvent for the radiation-sensitive resin composition. Among them, ester-based solvents and ketone-based solvents are preferable. As the ester-based solvents, acetate-based solvents are preferable, and n-butyl acetate and amyl acetate are more preferable. As the ketone-based solvents, chain ketones are preferable, and 2-heptanone is more preferable. The content of the organic solvent in the developer is preferably 80% by mass or more, more preferably 90% by mass or more, still more preferably 95% by mass or more, and particularly preferably 99% by mass or more. Examples of the components other than the organic solvent in the developer include water and silicon oil.

Examples of a development method include a method in which a substrate is immersed in a bath filled with a developer for a certain period of time (dipping method), a method in which a developer is allowed to be present on a surface of a substrate due to surface tension and to stand for a certain period of time (puddle method), a method in which a developer is sprayed onto a surface of a substrate (spray method), and a method in which a developer is discharged onto a substrate that is rotated at a constant speed while a developer discharge nozzle is scanned at a constant speed (dynamic dispensing method).

### EXAMPLES

Hereinafter, the present invention will specifically be described with reference to synthesis examples, examples, and comparative examples, but is not limited to the following examples. The methods for measuring various physical property values are described below.

### [Mw and Mn]

The Mw and the Mn of polymers were measured by gel permeation chromatography (GPC) using GPC columns manufactured by Tosoh Corporation (“G2000HXL”×2, “G3000HXL”×1, “G4000HXL”×1) under the following conditions.
Elution solvent: tetrahydrofuran (manufactured by Wako Pure Chemical Industries, Ltd.)
Flow rate: 1.0 mL/min
Sample concentration: 1.0% by mass
Amount of sample injected: 100 μL
Column temperature: 40° C.
Detector: differential refractometer
Standard substance: monodisperse polystyrene

### [Synthesis Examples] Synthesis of Base Resins (P-1) to (P-18)

The respective monomers were combined and subjected to a copolymerization reaction in a tetrahydrofuran (THF) solvent, and the reaction products were crystallized in methanol, and washed repeatedly with hexane, then isolated, and dried. Thus, base resins (P-1) to (P-18) having the compositions shown below were obtained. The composition of the obtained base polymers was confirmed by 1H-NMR, and the Mw and the dispersion degree (Mw/Mn) were confirmed under the above-described GPC conditions. The types and amounts of the monomers are shown in Table 1. In the following structural formulas, Me is a methyl group, Et is an ethyl group, and iPr is an isopropyl group.

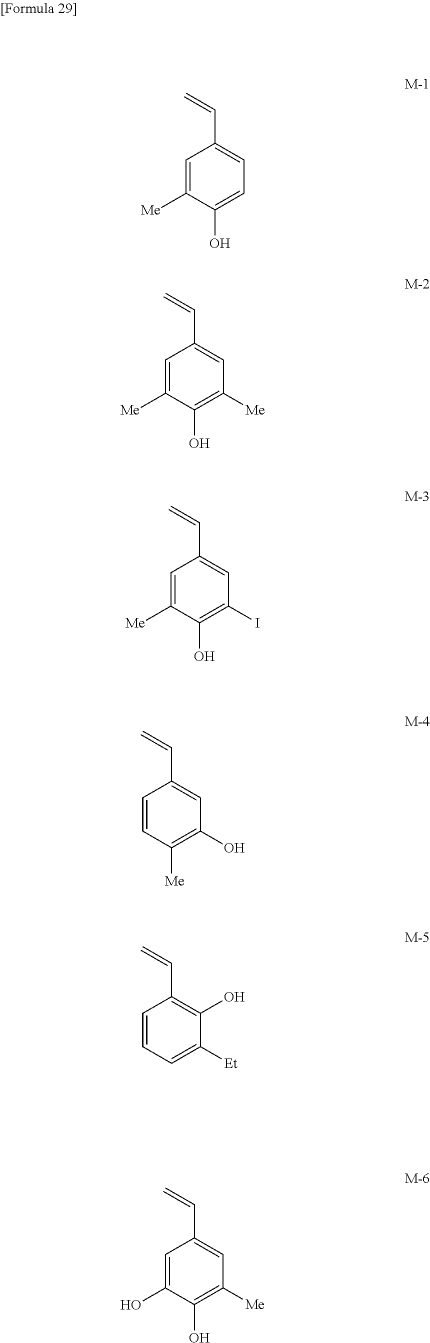

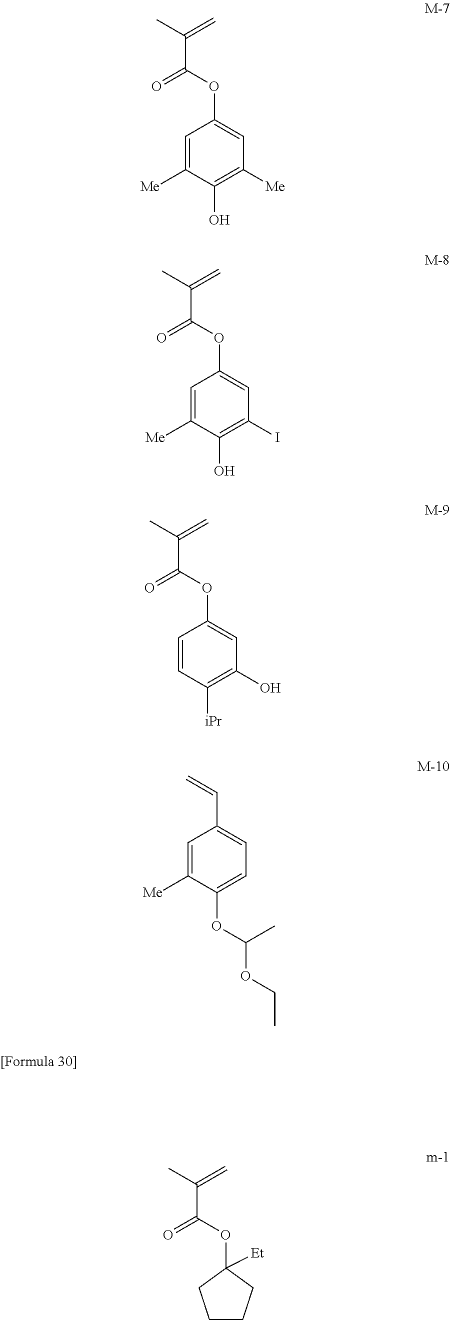

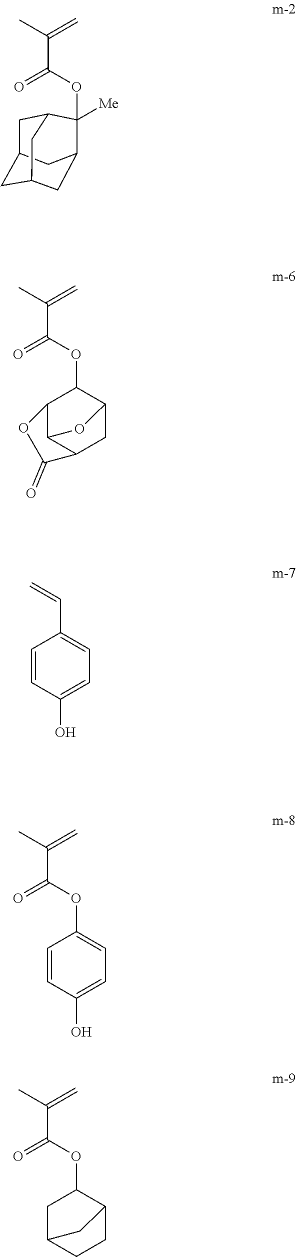

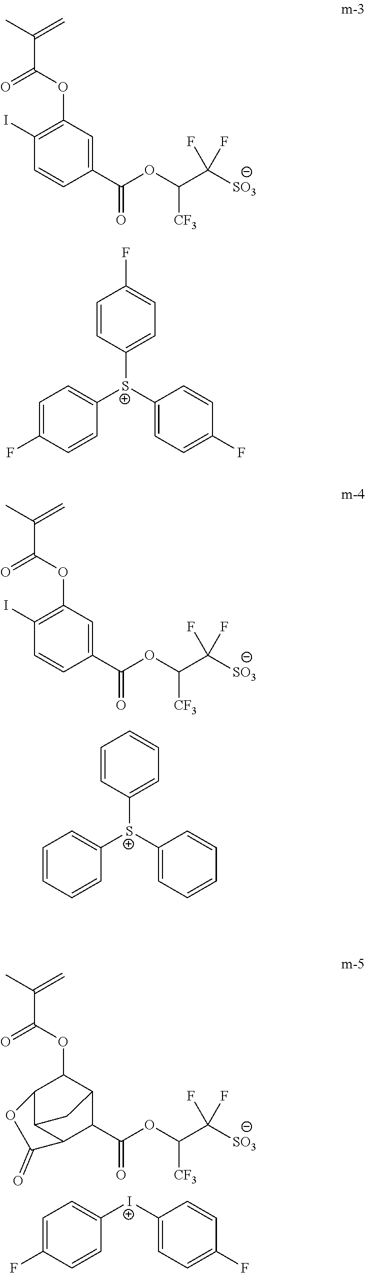

TABLE 1

| | | | | | | | | | | Other | | | |
|---|---|---|---|---|---|---|---|---|---|---|---|---|---|
| | | Structural unit A | | Structural unit B | | Structural unit D | | Structural unit E | | structural units | | | |
| | Resin | Type | Amount | Type | Amount | Type | Amount | Type | Amount | Type | Amount | Mw | Mw/Mn |
| Synthesis | P-1 | m-1/m-2 | 20/20 | m-3 | 10 | M-1 | 20 | m-6 | 30 | — | — | 8500 | 1.7 |
| Example 1 | | | | | | | | | | | | | |
| Synthesis | P-2 | m-1/m-2 | 20/20 | m-3 | 10 | M-2 | 20 | m-6 | 30 | — | — | 8700 | 1.7 |
| Example 2 | | | | | | | | | | | | | |
| Synthesis | P-3 | m-1/m-2 | 20/20 | m-3 | 10 | M-3 | 20 | m-6 | 30 | — | — | 9200 | 1.8 |
| Example 3 | | | | | | | | | | | | | |
| Synthesis | P-4 | m-1/m-2 | 20/20 | m-4 | 10 | M-4 | 20 | m-6 | 30 | — | — | 8600 | 1.7 |
| Example 4 | | | | | | | | | | | | | |
| Synthesis | P-5 | m-1/m-2 | 20/20 | m-3 | 10 | M-5 | 20 | m-6 | 30 | — | — | 8300 | 1.7 |
| Example 5 | | | | | | | | | | | | | |
| Synthesis | P-6 | m-1/m-2 | 20/20 | m-3 | 10 | M-6 | 20 | m-6 | 30 | — | — | 8600 | 1.6 |
| Example 6 | | | | | | | | | | | | | |
| Synthesis | P-7 | m-1/m-2 | 20/20 | m-3 | 10 | M-7 | 20 | m-6 | 30 | — | — | 8100 | 1.7 |
| Example 7 | | | | | | | | | | | | | |
| Synthesis | P-8 | m-1/m-2 | 20/20 | m-4 | 10 | M-8 | 20 | m-6 | 30 | — | — | 8300 | 1.8 |
| Example 8 | | | | | | | | | | | | | |
| Synthesis | P-9 | m-1/m-2 | 20/20 | m-3 | 10 | M-9 | 20 | m-6 | 30 | — | — | 8300 | 1.7 |
| Example 9 | | | | | | | | | | | | | |
| Synthesis | P-10 | m-1/m-2 | 20/20 | m-3 | 10 | M-1 | 2 | m-6 | 30 | m-7 | 18 | 8400 | 1.7 |
| Example 10 | | | | | | | | | | | | | |
| Synthesis | P-11 | m-1/m-2 | 20/20 | — | — | M-1 | 20 | m-6 | 30 | m-8 | 10 | 8900 | 1.7 |
| Example 11 | | | | | | | | | | | | | |
| Synthesis | P-12 | m-1/m-2 | 20/20 | — | — | M-2 | 20 | m-6 | 30 | m-9 | 10 | 9200 | 1.7 |
| Example 12 | | | | | | | | | | | | | |
| Synthesis | P-13 | m-1/m-2 | 20/20 | m-5 | 10 | M-1 | 20 | m-6 | 30 | — | — | 8400 | 1.7 |
| Example 13 | | | | | | | | | | | | | |
| Synthesis | P-14 | m-1/m-2 | 20/20 | m-4 | 10 | M-1 | 20 | m-6 | 30 | — | — | 8700 | 1.7 |
| Example 14 | | | | | | | | | | | | | |
| Synthesis | P-15 | m-1/m-2 | 20/20 | m-3 | 10 | — | — | m-6 | 30 | m-7 | 20 | 8400 | 1.7 |
| Example 15 | | | | | | | | | | | | | |
| Synthesis | P-16 | m-1/m-2 | 20/20 | m-3 | 10 | — | — | m-6 | 30 | m-8 | 20 | 8300 | 1.7 |
| Example 16 | | | | | | | | | | | | | |
| Synthesis | P-17 | m-1 | 60 | — | — | M-3 | 15 | — | — | m-7 | 25 | 7900 | 1.6 |
| Example 17 | | | | | | | | | | | | | |
| Synthesis | P-18 | m-2 | 35 | m-4 | 5 | M-10 | 10 | m-6 | 35 | m-7 | 15 | 8000 | 1.8 |
| Example 18 | | | | | | | | | | | | | |

The structures of the radiation-sensitive acid generators PAG1 to PAG4 and PAGcl used for the preparation of radiation-sensitive resin compositions are shown below.

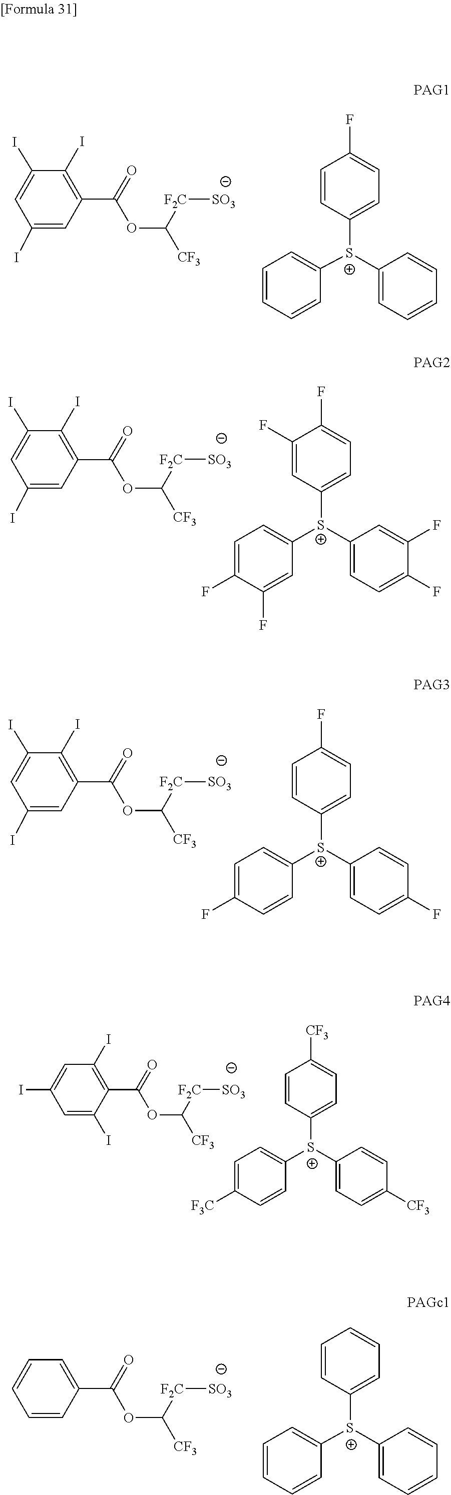

### Examples and Comparative Examples

A radiation-sensitive resin composition was prepared by dissolving the components with the composition given in Table 2 in a solvent containing 100 ppm of FC-4430 manufactured by 3M as a surfactant dissolved therein and then filtering the resulting solution through a 0.2 μm-sized filter.

In Table 2, the components are as follows.
Organic solvent: PGMEA (propylene glycol monomethyl ether acetate)
GBL (γ-butyrolactone)
CHN (cyclohexanone)
PGME (propylene glycol monomethyl ether)
DAA (diacetone alcohol)
EL (ethyl lactate)

### Acid Diffusion Controlling Agents (Q-1) to (Q-3) and (Qc-1)

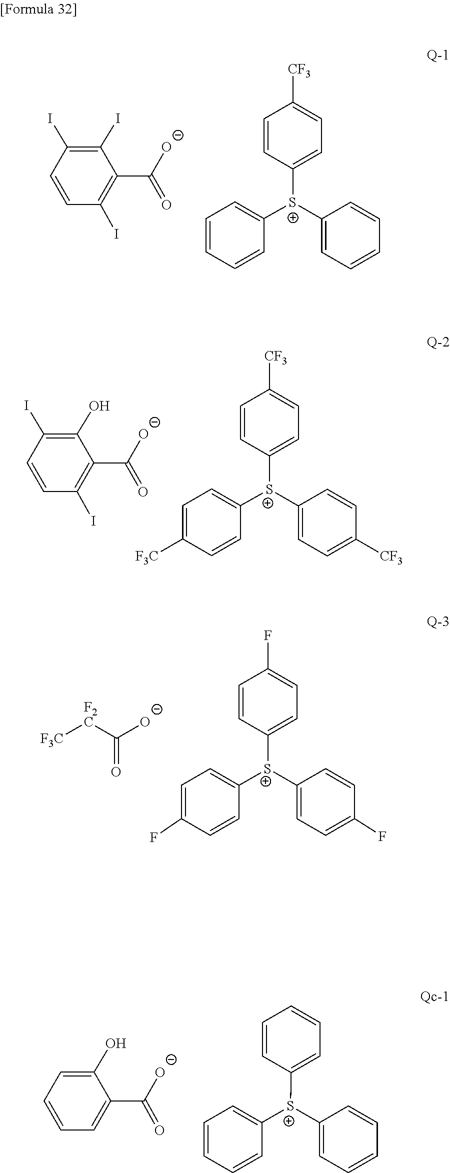

High fluorine-containing resin F-1: Mw=9,000, Mw/Mn=1.9

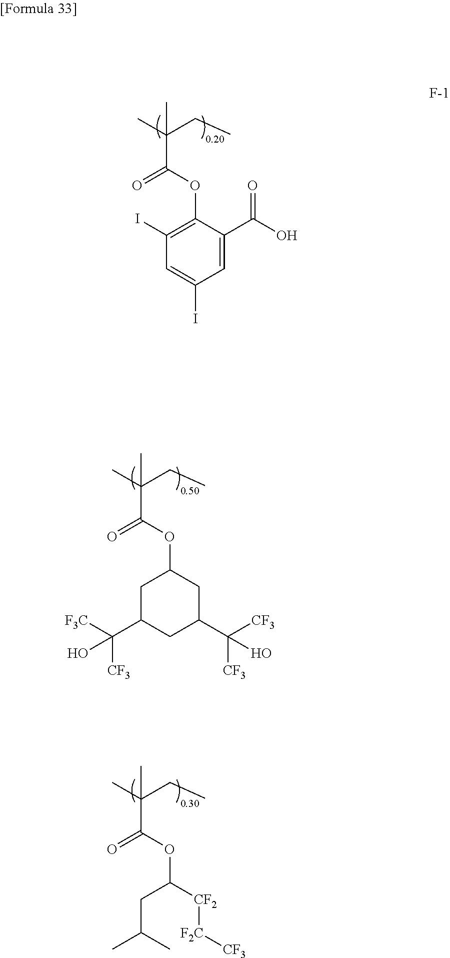

### Evaluation of Sensitivity by EUV Exposure

A composition for forming an antireflective film (“ARC66” manufactured by Brewer Science, Inc.) was applied onto a 12-inch silicon wafer using a spin coater (“CLEAN TRACK ACT12” manufactured by Tokyo Electron Limited), and then heated at 205° C. for 60 seconds to form an underlayer antireflective film having an average thickness of 10 nm. Each radiation-sensitive resin composition shown in Table 1 was applied onto the underlayer antireflection film using the spin coater, followed by performing PB at 130° C. for 60 seconds. Thereafter, cooling was performed at 23° C. for 30 seconds to form a resist film having an average thickness of 55 nm. This resist film was exposed to light using an EUV scanner (“NXE3300” (NA 0.33, σ 0.9/0.6, quadrupole illumination, hole pattern mask with a pitch of 46 nm on wafer and a bias of +20%) manufactured by ASML). PEB was performed on a hot plate at 120° C. for 60 seconds, and development was performed with a 2.38% by mass aqueous tetramethylammonium hydroxide (TMAH) solution for 30 seconds to form a resist pattern with a 23 nm hole and a 46 nm pitch. The exposure dose at which the resist pattern with a 23 nm hole and a 46 nm pitch was formed was defined as an optimum exposure dose (Eop), and the optimum exposure dose was defined as sensitivity (mJ/cm²).

### [Evaluation of CDU]

A resist pattern with a 23 nm hole and a 46 nm pitch was formed through the same operation as that described above by applying the exposure dose Eop determined above. The resist pattern formed was observed from the top of the pattern using a scanning electron microscope (“CG-5000” manufactured by Hitachi High-Technologies Corporation). The hole diameter was measured at 16 points in a range of 500 nm and the average value thereof was determined. In addition, the average value was measured at arbitrary 500 points in total. The 3 sigma value was determined from the distribution of the measurement values, and the 3 sigma value determined was taken as an evaluation value (nm) of CDU performance. The smaller an evaluation value of CDU performance is, the smaller the dispersion of hole diameter in a long period is and the better the CDU performance is. The results are shown in Table 2. The numerical values in the parentheses in the columns of sensitivity and CDU of Table 2 are the improvement rates (%) based on the evaluation results of Comparative Examples 3 to 4.

TABLE 2

| | Base resin | PAG | Acid diffusion | | Additive | | | |
|---|---|---|---|---|---|---|---|---|
| | (parts by | (parts by | controlling agent | Solvent | (parts by | Sensitivity | CDU | Development |
| | mass) | mass) | (parts by mass) | (parts by mass) | mass) | [mJ/cm²] | [nm] | defects |
| Example 1 | P-1 | — | Qc-1 | PGMEA/DAA | F-1 | 14 | 2.4 | A |
| | (100) | | (3.0) | (2,000/500) | (3.0) | (12.5%) | (—) | |
| Example 2 | P-2 | — | Qc-1 | PGMEA/DAA | F-1 | 14 | 2.4 | A |
| | (100) | | (3.0) | (2,000/500) | (3.0) | (12.5%) | (—) | |
| Example 3 | P-3 | — | Qc-1 | PGMEA/DAA | F-1 | 14 | 2.4 | A |
| | (100) | | (3.0) | (2,000/500) | (3.0) | (12.5%) | (—) | |
| Example 4 | P-4 | PAG3 | Qc-1 | PGMEA/DAA | F-1 | 14 | 2.2 | A |
| | (100) | (2.0) | (3.0) | (2,000/500) | (3.0) | (12.5%) | (8.5%) | |
| Example 5 | P-5 | — | Qc-1 | PGMEA/DAA | F-1 | 14 | 2.4 | A |
| | (100) | | (3.0) | (2,000/500) | (3.0) | (12.5%) | (—) | |
| Example 6 | P-6 | — | Qc-1 | PGMEA/DAA | F-1 | 14 | 2.4 | A |
| | (100) | | (3.0) | (2,000/500) | (3.0) | (12.5%) | (—) | |
| Example 7 | P-7 | — | Qc-1 | PGMEA/DAA | F-1 | 14 | 2.4 | A |
| | (100) | | (3.0) | (2,000/500) | (3.0) | (12.5%) | (—) | |
| Example 8 | P-8 | — | Q-3 | PGMEA/DAA | F-1 | 14 | 2.4 | A |
| | (100) | | (3.0) | (2,000/500) | (3.0) | (12.5%) | (—) | |
| Example 9 | P-9 | — | Qc-1 | PGMEA/DAA | F-1 | 14 | 2.4 | A |
| | (100) | | (3.0) | (2,000/500) | (3.0) | (12.5%) | (—) | |
| Example 10 | P-10 | — | Qc-1 | PGMEA/GBL | F-1 | 14 | 2.4 | B |
| | (100) | | (3.0) | (2,200/300) | (3.0) | (12.5%) | (—) | |
| Example 11 | P-11 | PAG1 | Qc-1 | PGMEA/GBL | F-1 | 15 | 2.2 | A |
| | (100) | (10) | (3.0) | (2,200/300) | (3.0) | (6%) | (8.5%) | |
| Example 12 | P-11 | PAG3 | Qc-1 | PGMEA/GBL | F-1 | 14 | 2.2 | A |
| | (100) | (7.5) | (3.0) | (2,200/300) | (3.0) | (12.5%) | (8.5%) | |
| Example 13 | P-11 | PAG2 | Qc-1 | PGMEA/GBL | F-1 | 13 | 2.2 | A |
| | (100) | (4.0) | (3.0 | (2,200/300) | (3.0) | (19%) | (8.5%) | |
| Example 14 | P-12 | PAGc1 | Q-1 | PGMEA/PGME | F-1 | 15 | 2.2 | A |
| | (100) | (7.5) | (5.0) | (2,000/500) | (3.0) | (6%) | (8.5%) | |
| Example 15 | P-12 | PAGc1 | Q-2 | PGMEA/GBL | F-1 | 14 | 2.2 | A |
| | (100) | (7.5) | (1.5) | (2,200/300) | (3.0) | (12.5%) | (8.5%) | |
| Example 16 | P-13 | PAG4 | Q-3 | PGMEA/CHN/PGME | F-1 | 14 | 2.2 | A |
| | (100) | (1.0) | (5.0) | (800/1,500/200) | (3.0) | (12.5%) | (8.5%) | |
| Example 17 | P-17 | PAG3 | Q-2 | PGMEA/PGME | F-1 | 14 | 2.2 | A |
| | (100) | (8.5) | (5.5) | (2,200/300) | (3.0) | (12.5%) | (8.5%) | |
| Example 18 | P-18 | PAG2 | Q-1 | PGMEA/DAA | F-1 | 13 | 2.2 | A |
| | (100) | (4.5) | (10.0) | (2,000/500) | (3.0) | (19%) | (8.5%) | |
| Comparative | P-15 | — | Q-1 | PGMEA/CHN | F-1 | 14 | 2.2 | C |
| Example 1 | (100) | | (5.0) | (2,000/500) | (3.0) | (12.5%) | (8.5%) | |
| Comparative | P-16 | — | Q-2 | PGMEA/CHN/PGME | F-1 | 14 | 2.2 | C |
| Example 2 | (100) | | (2.0) | (400/2,000/100) | (3.0) | (12.5%) | (8.5%) | |
| Comparative | P-14 | PAGc1 | Qc-1 | PGMEA/PGME/EL | F-1 | 16 | 2.4 | A |
| Example 3 | (100) | (2.0) | (1.5) | (1,500/500/500) | (3.0) | (—) | (—) | |
| Comparative | P-11 | PAGc1 | Qc-1 | PGME/EL | F-1 | 16 | 2.4 | A |
| Example 4 | (100) | (10) | (3.0) | (500/2,000) | (3.0) | (—) | (—) | |

The evaluation conducted for the resist patterns formed through the EUV exposure revealed that all the radiation-sensitive resin compositions of Examples were good in sensitivity, CDU, and development residue.

### INDUSTRIAL APPLICABILITY

According to the radiation-sensitive resin composition and the resist pattern formation method described above, a resist pattern having good sensitivity to exposure light and being superior in CDU performance and development residue can be formed. Therefore, these composition and method can suitably be used for a machining process and the like of a semiconductor device that is expected to be further miniaturized in the future.

1: A radiation-sensitive resin composition comprising:
a resin comprising: a structural unit A which comprises an acid-dissociable group; and a structural unit D which comprises an aromatic ring, the aromatic ring having a phenolic hydroxy group and an alkyl group thereon; and
a solvent,
wherein
the structural unit D has the phenolic hydroxy group and the alkyl group on the same aromatic ring,
in the aromatic ring of the structural unit D, the alkyl group is bonded to a carbon atom adjacent to a carbon atom to which the phenolic hydroxy group is bonded,
provided that the radiation-sensitive resin composition satisfies at least one selected from the group consisting of Conditions 1 and 2,
Condition 1: the resin further comprises a structural unit B which comprises an organic acid anion moiety and an onium cation moiety, the onium cation moiety comprising an aromatic ring structure having a fluorine atom, and the resin is a radiation sensitive acid generating resin which generates an acid through irradiation with radiation,
Condition 2: the radiation-sensitive resin composition further comprises an onium salt which comprises an organic acid anion moiety and an onium cation moiety, the onium cation moiety comprising an aromatic ring structure having a fluorine atom, and the onium salt is not the radiation-sensitive acid generating resin.

2: The radiation-sensitive resin composition according to claim 1, wherein the structural unit D is represented by formula (D), 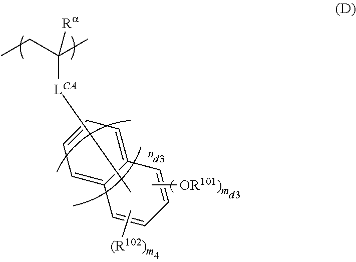
wherein, in the formula (D),
R^{α} is a hydrogen atom, a fluorine atom, a methyl group, or a trifluoromethyl group;
L^{CA} is a single bond, —COO—*, or —O—; * is a bond on the aromatic ring side;
R¹⁰¹ is a hydrogen atom or a protective group to be deprotected by the action of an acid; when there are two or more R¹⁰¹s, the plurality of R¹⁰¹s is the same as or different from each other, provided that at least one R¹⁰¹ is a hydrogen atom;
R¹⁰² is a cyano group, a nitro group, an alkyl group, a fluorinated alkyl group, an alkoxycarbonyloxy group, an acyl group, or an acyloxy group, provided that at least one R¹⁰² is an alkyl group;
n_{d3} is an integer of 0 to 2, m_{d3} is an integer of 1 to 8, and m₄ is an integer of 1 to 8, provided that 1≤m_{d3}+m₄≤2n_{d3}+5 is satisfied;
in the formula (D), the alkyl group represented by R¹⁰² is bonded to a carbon atom adjacent to a carbon atom to which the phenolic hydroxy group represented by OR¹⁰¹ is bonded.

3: The radiation-sensitive resin composition according to claim 1, wherein the structural unit A is represented by formula (1), 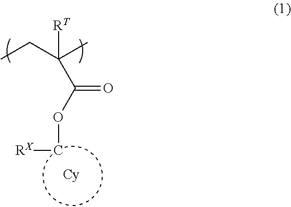
wherein, in the formula (1),
R^{T} is a hydrogen atom, a fluorine atom, a methyl group, or a trifluoromethyl group;
R^{X} is a monovalent hydrocarbon group having 1 to 20 carbon atoms; and
Cy represents an alicyclic structure having 3 to 20 ring members and formed together with the carbon atom to which Cy is bonded.

4: The radiation-sensitive resin composition according to claim 1, wherein the onium cation comprising an aromatic ring structure having a fluorine atom is represented by formula (Q-1), 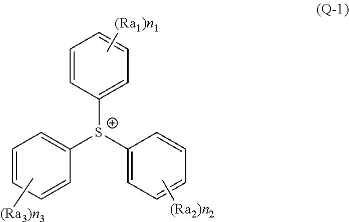
wherein, in the formula (Q-1),
Ra₁ and Ra₂ each independently represent a substituent;
n₁ represents an integer of 0 to 5, and when n₁ is 2 or more, the plurality of Ra₁'s are the same or different;
n₂ represents an integer of 0 to 5, and when n₂ is 2 or more, the plurality of Ra₂'s are the same or different;
n₃ represents an integer of 1 to 5, and when n₃ is 2 or more, the plurality of Ra₃'s are the same or different;
Ra₃ represents a fluorine atom or a group comprising one or more fluorine atoms;
when n₁ is 2 or more, the plurality of Ra₁'s are optionally taken together represent a ring;
when n₂ is 2 or more, the plurality of Ra₂'s are optionally taken together represent a ring; and
when n₁ is 1 or more and n₂ is 1 or more, Rₐ₁ and Ra₂ are optionally taken together represent a ring.

5: The radiation-sensitive resin composition according to claim 1, wherein the resin comprises an iodine-substituted aromatic ring structure.

6: The radiation-sensitive resin composition according to claim 1, wherein the radiation-sensitive resin composition satisfies the Condition 1, and
the resin further comprises at least one selected from the group consisting of:
a radiation-sensitive acid generator comprising an organic acid anion moiety and an onium cation moiety, provided that the radiation-sensitive acid generator is not the radiation-sensitive acid generating resin; and
an acid diffusion controlling agent comprising an organic acid anion moiety and an onium cation moiety and being to generate an acid having a pKa higher than a pKa of an acid to be generated from the radiation-sensitive acid generator through irradiation with radiation, provided that the acid diffusion controlling agent is not the radiation-sensitive acid generating resin.

7: The radiation-sensitive resin composition according to claim 1, wherein the structural unit B is derived from a monomer represented by formula (2) or a monomer represented by formula (3), 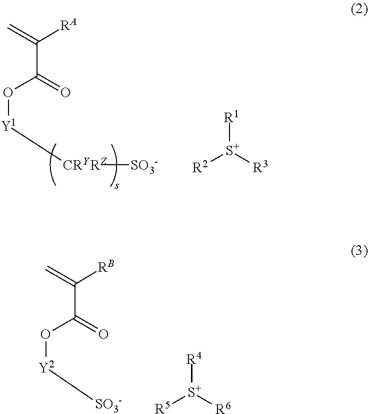
wherein, in the formulas (2) and (3),
R^{A} and R^{B} are each a hydrogen atom, a fluorine atom, a methyl group, or a trifluoromethyl group;
R^{Y} and R^{Z} are independently a hydrogen atom, a fluorine atom, or a fluorinated hydrocarbon group, and at least one of R and R^{Z} is a fluorine atom or a fluorinated hydrocarbon group; when there are a plurality of R^{Y}s, the plurality of R^{Y}s are the same or different, and there are a plurality of R^{Z}s, the plurality of R^{Z}s are the same or different;
s is an integer of 1 to 20;
R¹ to R³ are independently a monovalent hydrocarbon group, and at least one of R¹ to R³ is an aromatic ring having a fluorine atom;
R⁴ to R⁶ are independently a monovalent hydrocarbon group, and at least one of R⁴ to R⁶ is an aromatic ring having a fluorine atom;
Y¹ is a single bond or —Y¹—C(═O)—O—; Y¹ is a divalent hydrocarbon group having 1 to 20 carbon atoms or a divalent group in which a hetero atom is introduced into a hydrocarbon group having 1 to 20 carbon atoms;
Y² is a single bond, a methylene group, an ethylene group, a phenylene group, a fluorinated phenylene group, —O—Y²¹—, —C(═O)—O—Y²¹—, or —C(═O)—NH—Y²¹—; Y²¹ is an alkanediyl group having 1 to 6 carbon atoms, an alkenediyl group having 2 to 6 carbon atoms, a phenylene group, or a modified group in which a carbonyl group, an ester linkage, an ether linkage, or a hydroxy group is introduced into the alkanediyl group, the alkenediyl group, or the phenyl group; and the alkanediyl group, the alkenediyl group, the phenylene group, and the modified group are each optionally substituted with a fluorine atom.

8: The radiation-sensitive resin composition according to claim 1, wherein the radiation-sensitive resin composition satisfies the Condition 2,
the onium salt comprises at least one selected from the group consisting of:
a radiation-sensitive acid generator comprising an organic acid anion moiety and an onium cation moiety; and
an acid diffusion controlling agent comprising an organic acid anion moiety and an onium cation moiety and being to generate an acid having a pKa higher than a Kpa of an acid to be generated from the radiation-sensitive acid generator through irradiation with radiation, and
when both the radiation-sensitive acid generator and the acid diffusion controlling agent are included in the onium salt, at least one of the onium cation moiety constituting the radiation-sensitive acid generator and the onium cation moiety constituting the acid diffusion controlling agent comprises an aromatic ring structure having a fluorine atom, and
when either one of the radiation-sensitive acid generator or the acid diffusion controlling agent is included in the onium salt, the onium cation moiety constituting the included radiation-sensitive acid generator or the included acid diffusion controlling agent comprises an aromatic ring structure having a fluorine atom.

9: The radiation-sensitive resin composition according to claim 6, wherein the organic acid anion moiety of at least one selected from the radiation-sensitive acid generator and the acid diffusion controlling agent comprises an iodine-substituted aromatic ring structure.

10: The radiation-sensitive resin composition according to claim 8, wherein the organic acid anion moiety of at least one selected from the radiation-sensitive acid generator and the acid diffusion controlling agent comprises an iodine-substituted aromatic ring structure.

11: A pattern formation method comprising:
directly or indirectly applying the radiation-sensitive resin composition according to claim 1 to a substrate to form a resist film;
exposing the resist film to light; and
developing, with a developer, the resist film exposed.

12: The pattern formation method according to claim 11, wherein exposing comprises exposing the resist film to extreme ultraviolet ray or electron beam.
